(19) United States
(12) Patent Application Publication
(10) Pub. No.: US 2024/0006417 A1
(43) Pub. Date: Jan. 4, 2024

(54) SEMICONDUCTOR STRUCTURE

(71) Applicant: Taiwan Semiconductor Manufacturing Company, Ltd., Hsinchu (TW)

(72) Inventor: Jhon-Jhy LIAW, Zhudong Township (TW)

(73) Assignee: Taiwan Semiconductor Manufacturing Company, Ltd., Hsinchu (TW)

(21) Appl. No.: 17/853,543

(22) Filed: Jun. 29, 2022

(51) Int. Cl. H01L 27/118

(52) U.S. Cl. CPC H01L 27/11807; H01L 2027/11831; H01L 2027/11881

(57) ABSTRACT

A semiconductor structure is provided. The semiconductor structure includes a first transistor. The first transistor includes a first set of nanostructures vertically stacked and spaced apart from one another, a first gate stack wrapping around the first set of nanostructures and extending in a first direction, and a first source/drain feature and a second source/drain feature adjoining opposite sides of the first set of nanostructures. The semiconductor structure also includes a first contact plug over the first source/drain feature and a second contact plug over the second source/drain feature. As measured in a second direction which is perpendicular to the first direction, a width of the second contact plug is greater than a width of the first contact plug.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIG. 2A, 2A-1, 2A-2 and 2A-3, 2B, 2B-1, 2B-2 and 2B-3, 2C, 2C-1, 2C-2, 2C-3 and 2C-4, 2D, 2D-1, 2D-2, 2D-3 and 2D-4, and 2E, 2E-1, 2E-2, 2E-3 and 2E-4 are schematic views illustrating the formation of a semiconductor structure, in accordance with some embodiments of the disclosure.

FIG. 3A and 3B, 3B-1, 3B-2, 3B-3 and 3B-4 are schematic views illustrating the formation of a semiconductor structure, in accordance with some embodiments of the disclosure.

FIG. 4 is a modification of the semiconductor structure of FIGS. 2E-1, in accordance with some embodiments of the disclosure.

FIG. 5 is a modification of the semiconductor structure of FIGS. 2E-1, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure are provided. The semiconductor structure may include a functional transistor and an isolation transistor, and a contact plug on the source/drain feature shared by the functional transistor and the isolation transistor. Because the contact plug and the gate stack of the isolation transistor are electrically connected to each other, the contact plug may be formed close to the isolation transistor without negatively impacting the contact-to-gate isolation margin. Therefore, the width of the contact plug may be enlarged toward the gate stack of the isolation transistor, and thus the performance of the resulting semiconductor devices may be enhanced.

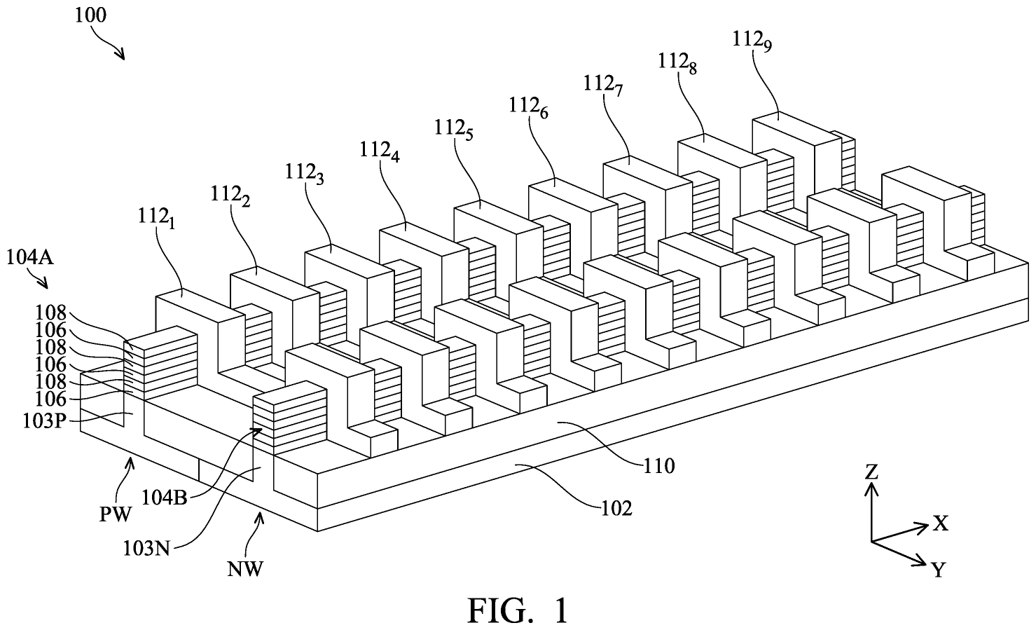

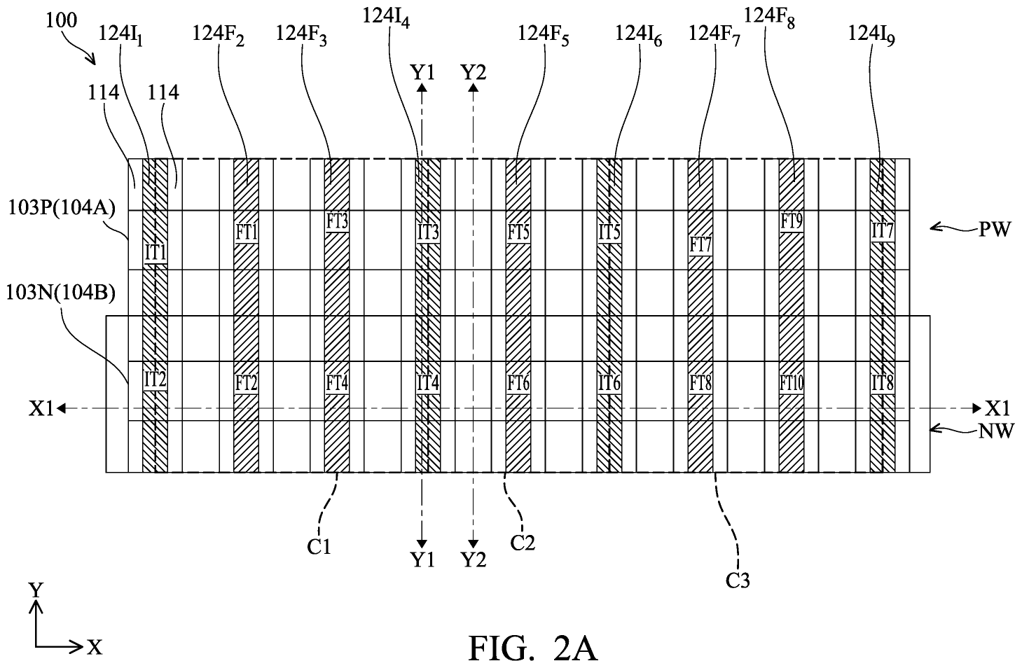

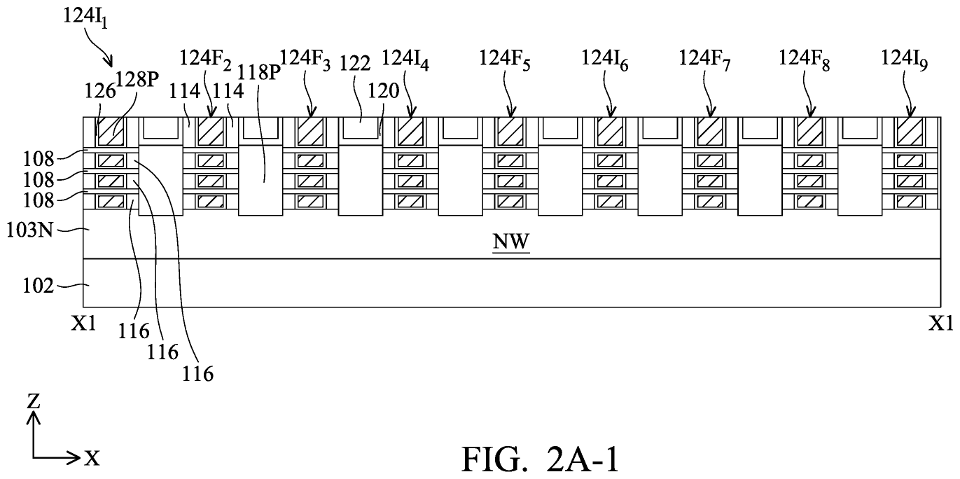

FIG. 1 is a perspective view of a semiconductor structure 100, in accordance with some embodiments of the disclosure.

The semiconductor structure 100 includes a substrate 102 and fin structures 104 (including 104A and 104B) over the substrate 102, as shown in FIG. 1, in accordance with some embodiments. The substrate 102 includes a p-type well PW and an n-type well NW immediately adjacent to the p-type well PW, in accordance with some embodiments. The fin structure 104A is formed in the p-type well PW of the substrate 102, and the fin structure 104B is formed in the n-type well NW of the substrate 102, in accordance with some embodiments. The fin structures 104A and 104B are the active regions of the semiconductor structure 100, in accordance with some embodiments.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The fin structure 104A includes a lower fin element 103P formed from the p-type well PW, and the fin structure 104B includes a lower fin element 103N formed from the n-type well NW, in accordance with some embodiments. The lower fin elements 103P and 103N are surrounded by an isolation structure 110, in accordance with some embodiments. Each of the fin structures 104A and 104B further includes an upper fin element formed from an epitaxial stack including alternating first semiconductor layers 106 and second semiconductor layer 108, in accordance with some embodiments. The second semiconductor layers 108 will form nanostructures (e.g., nanowires or nanosheets) and serve as the channel for the resulting semiconductor devices, in accordance with some embodiments.

The fin structures 104 extend in X direction, in accordance with some embodiments. That is, the fin structures 104 have longitudinal axes parallel to the X direction, in accordance with some embodiments. The X direction may also be referred to as the channel-extending direction. The current of the resulting semiconductor device (i.e., nanostructure transistor) flows in the X direction through the channel. Each of the fin structures 104 is defined as several channel regions and several source/drain regions, where the channel regions and the source/drain regions are alternately arranged, in accordance with some embodiments. In this disclosure, a source/drain refers to a source and/or a drain. It is noted that in the present disclosure, a source and a drain are interchangeably used and the structures thereof are substantially the same. Gate structures 112 (including 112₁-112₉) are formed with longitudinal axes parallel to the Y direction and extending across and/or surrounding the channel regions of the fin structures 104A and 104B, in accordance with some embodiments. The source/drain regions of the fin structures 104A and 104B are exposed from the gate structures 112, in accordance with some embodiments. The Y direction may also be referred to as a gate-extending direction.

Although two fin structures 104 are illustrated in FIG. 1, the semiconductor structure 100 may include more than two fin structures 104. In addition, FIG. 1 shows nine gate structures 112 (or channel regions) for illustrative purposes and is not intended to be limiting. The number of fin structures and the gate structures may be dependent on design demand of an integrated circuit and/or performance consideration of semiconductor devices.

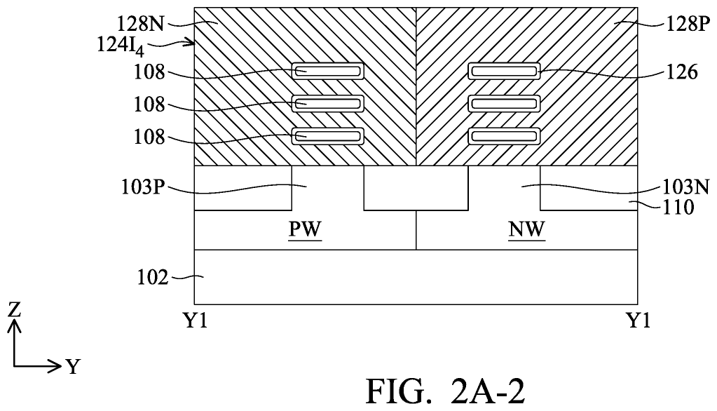

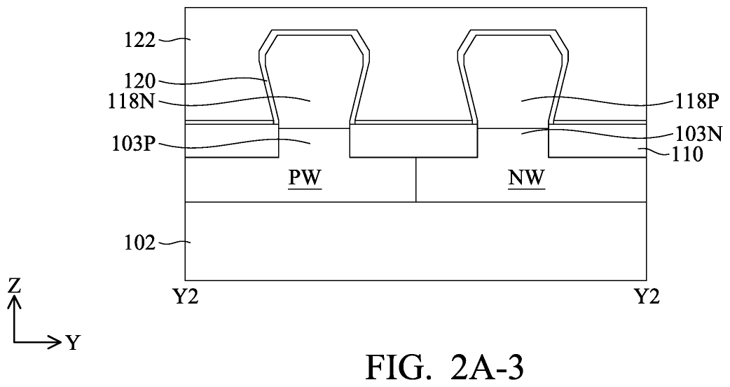

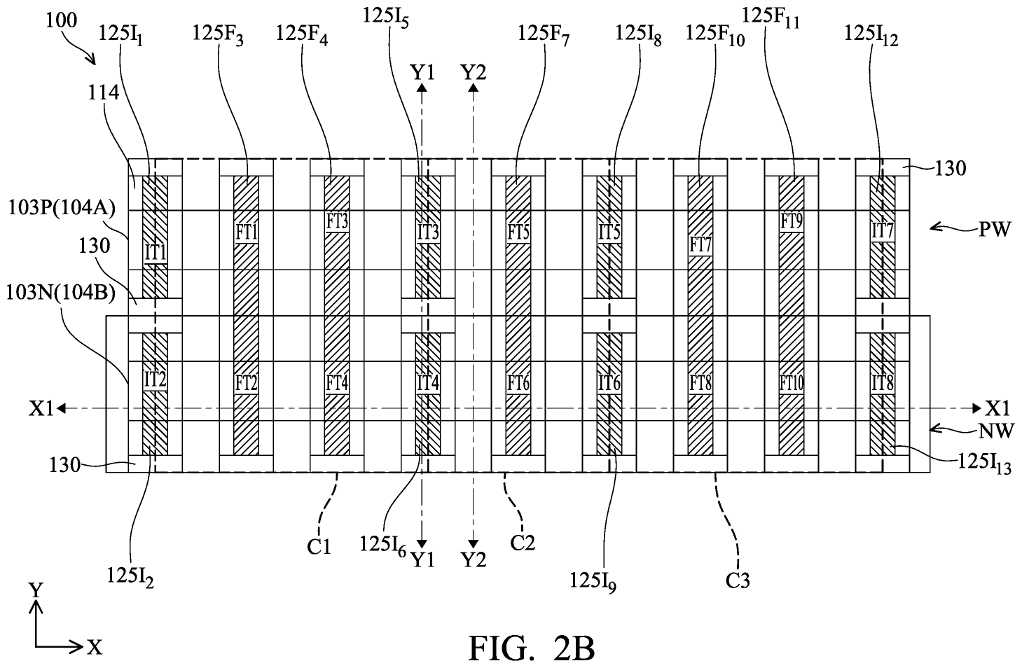

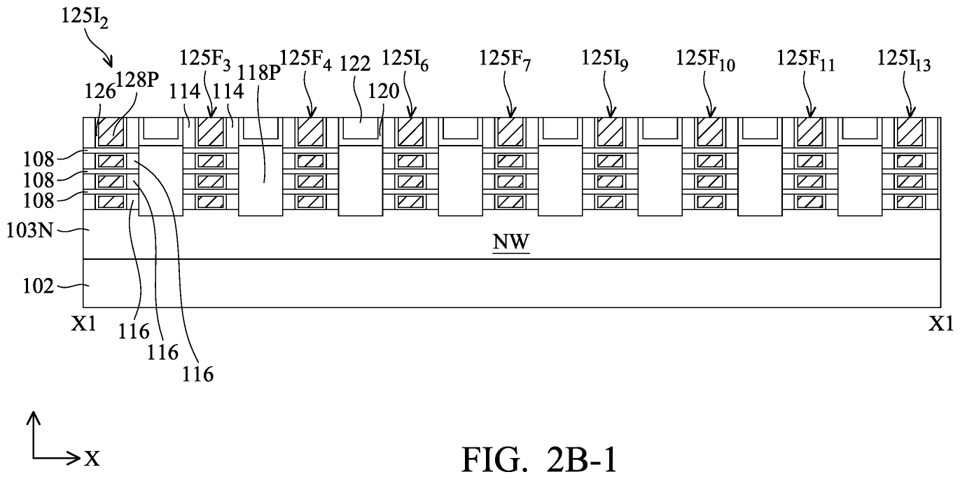

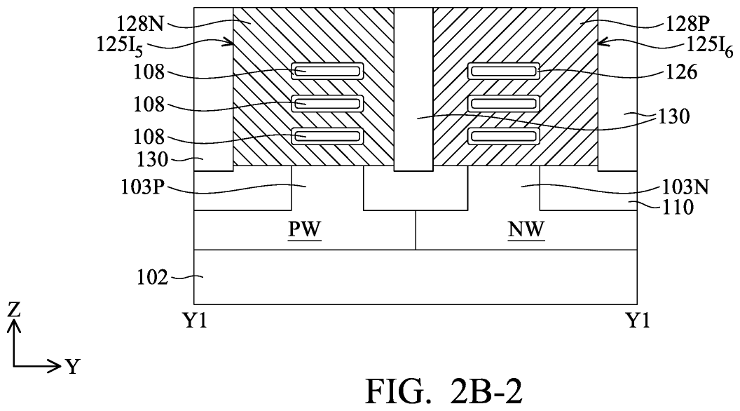

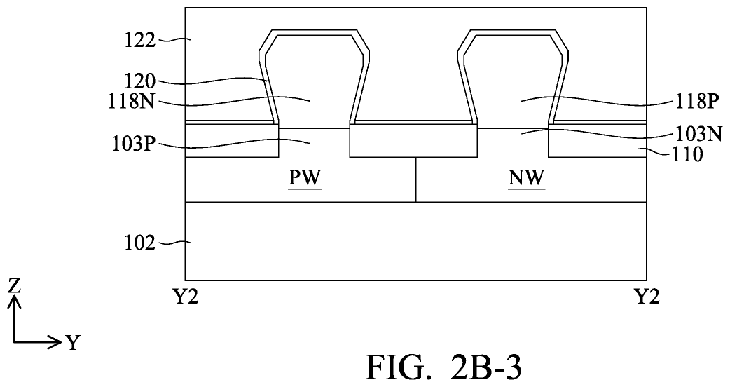

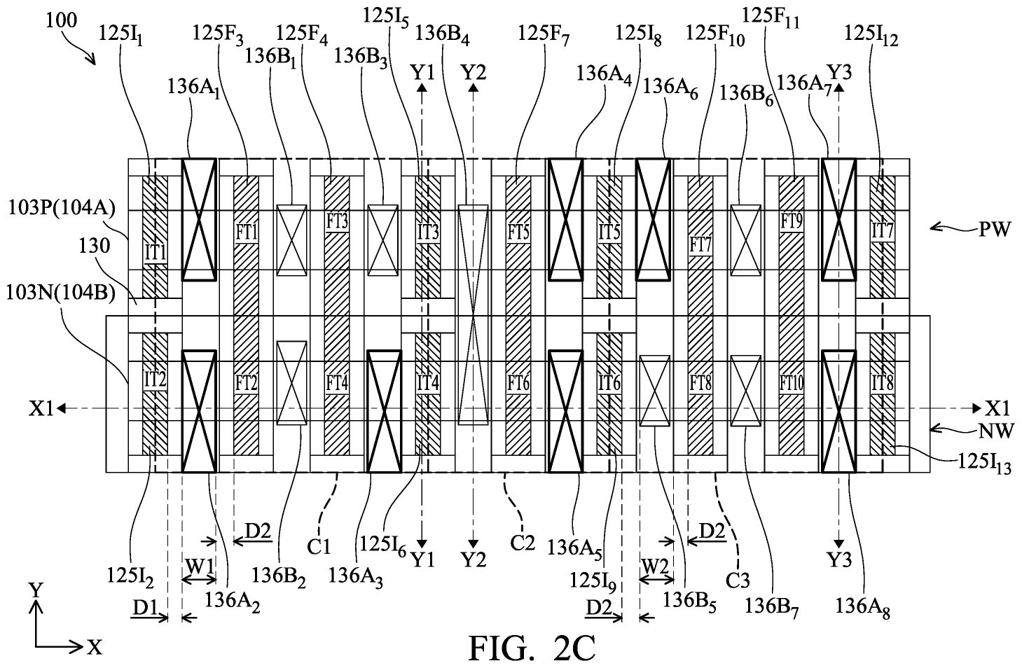

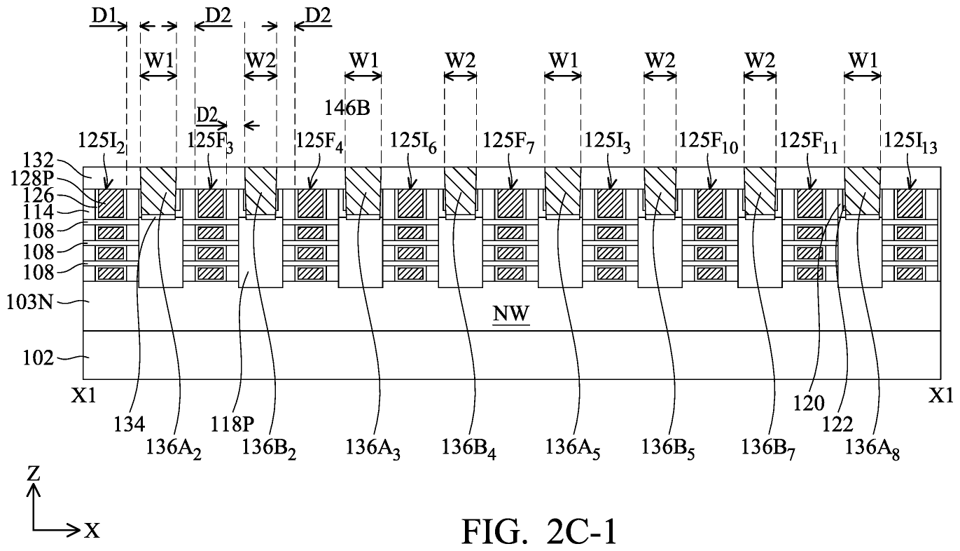

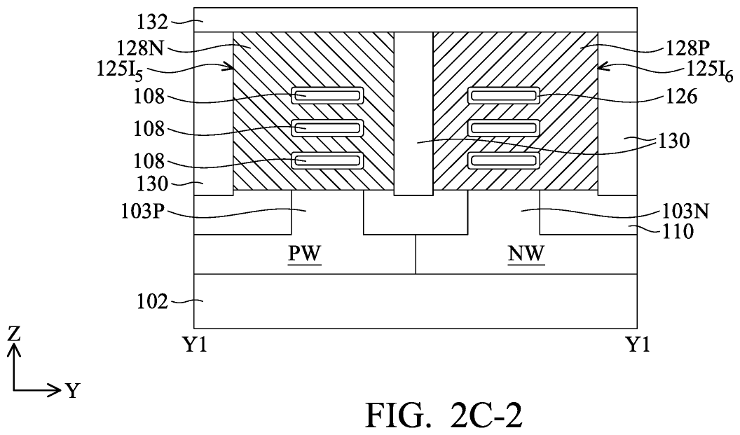

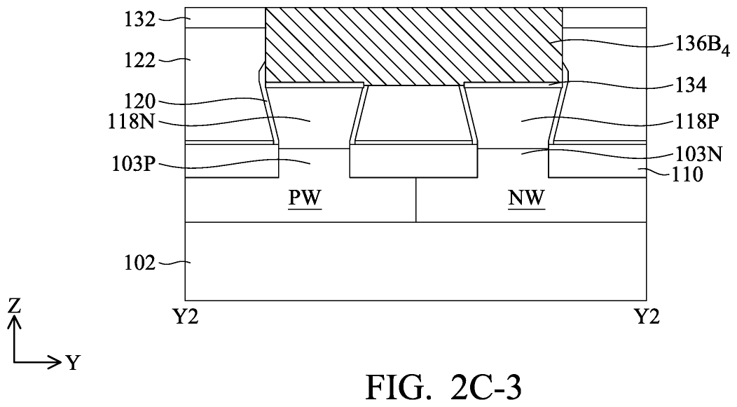

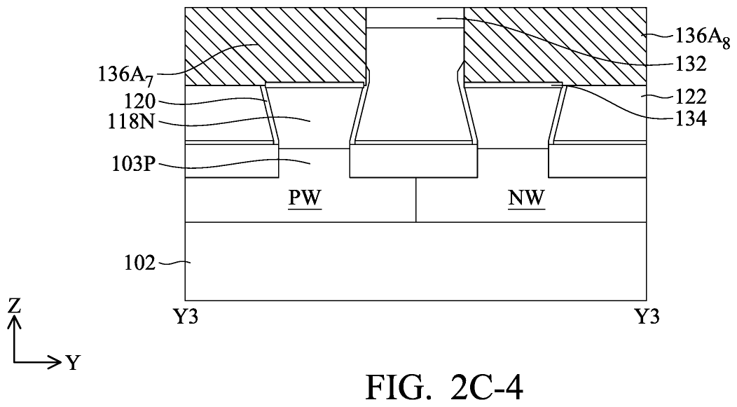

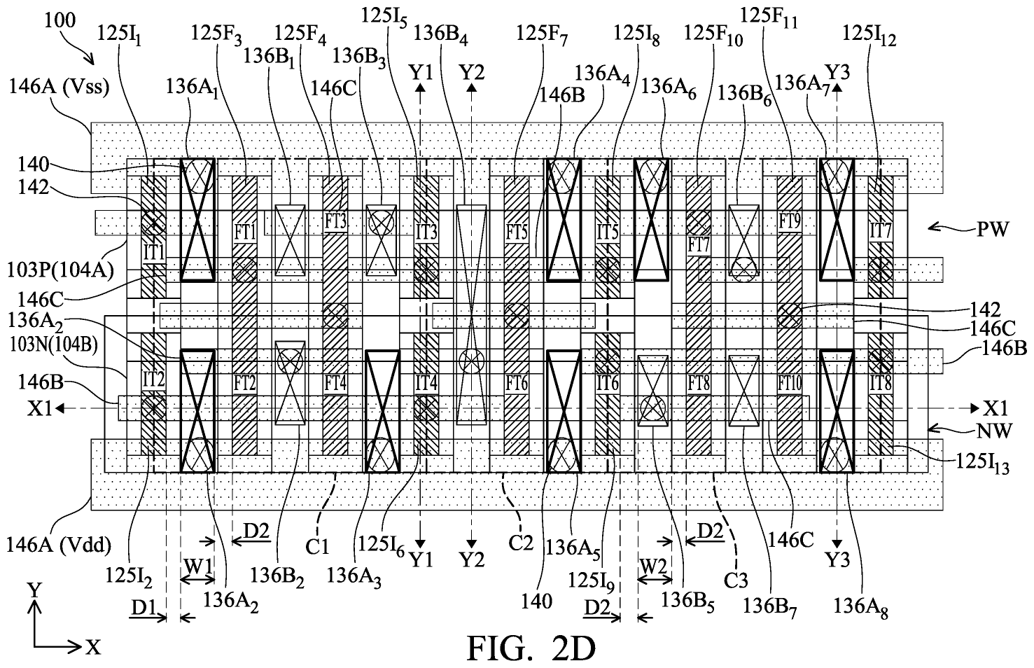

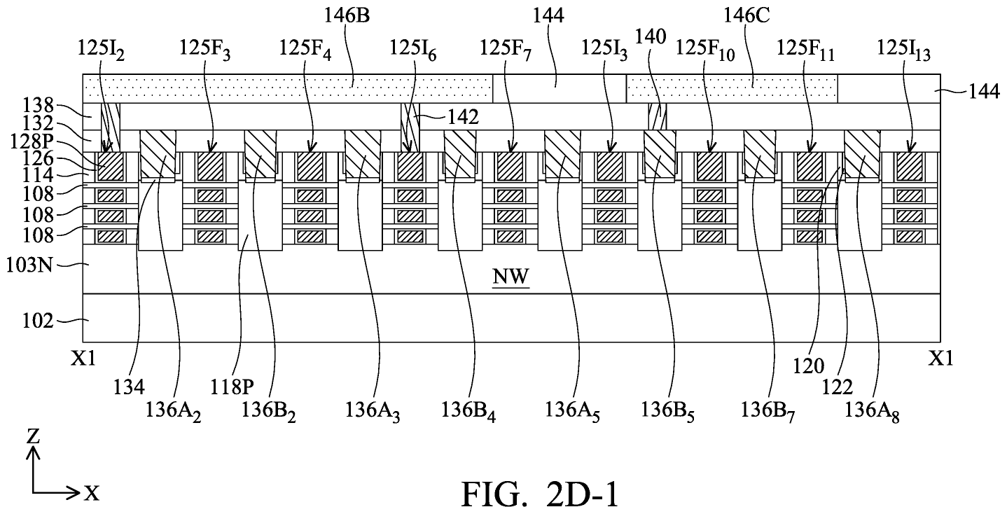

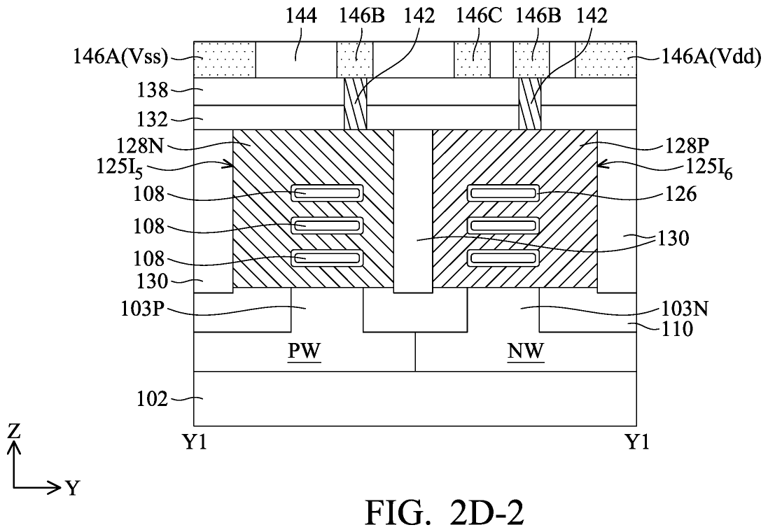

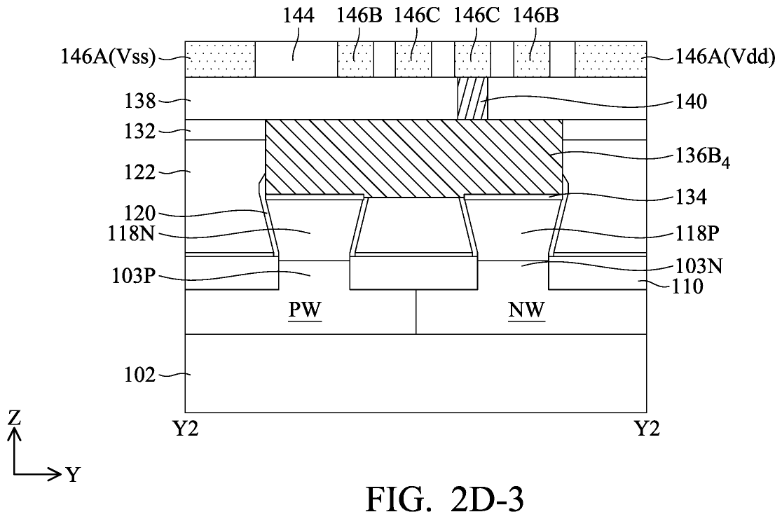

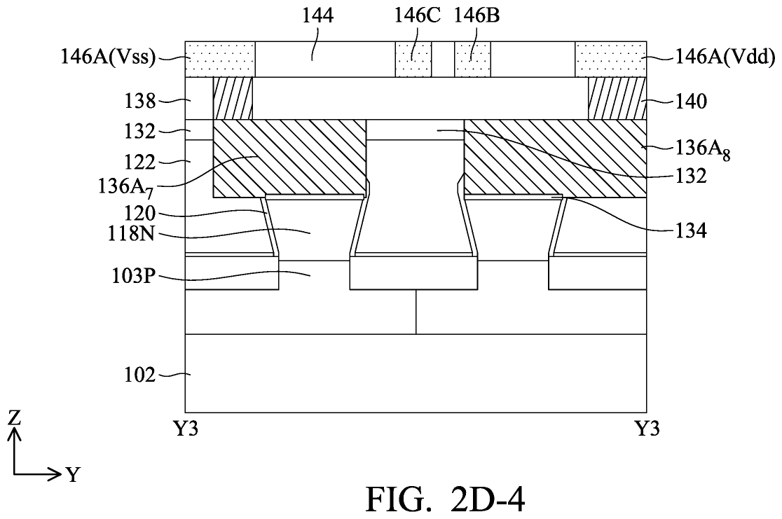

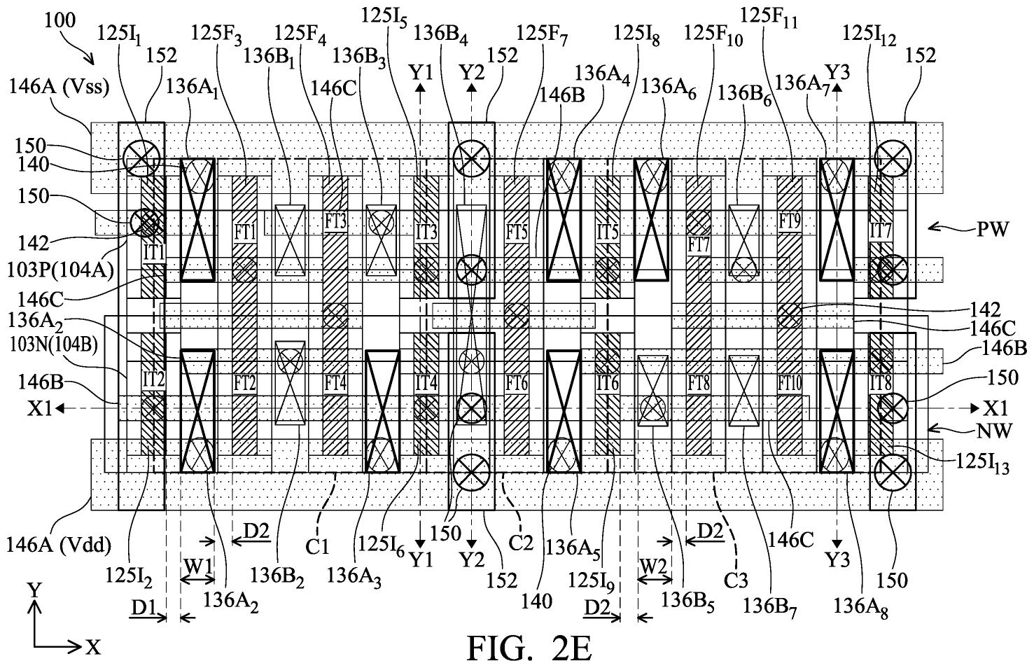

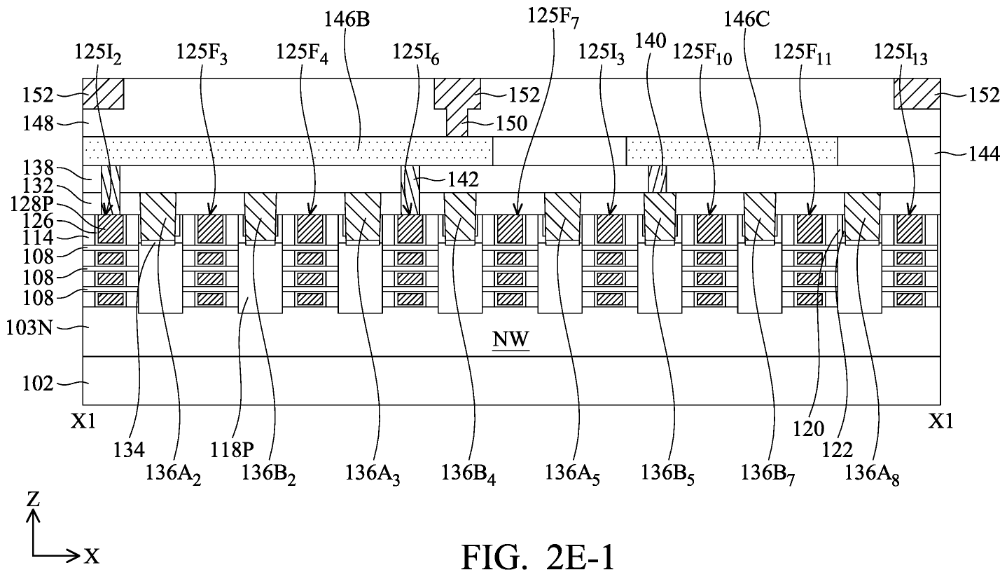

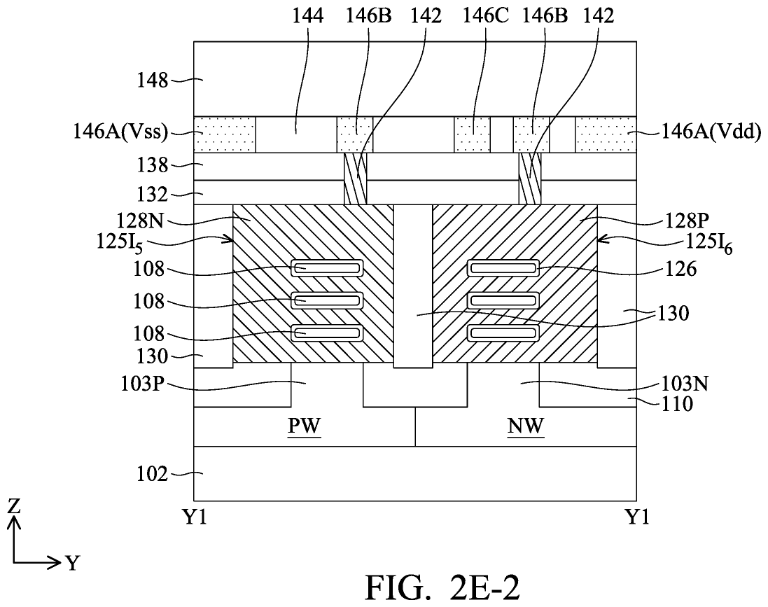

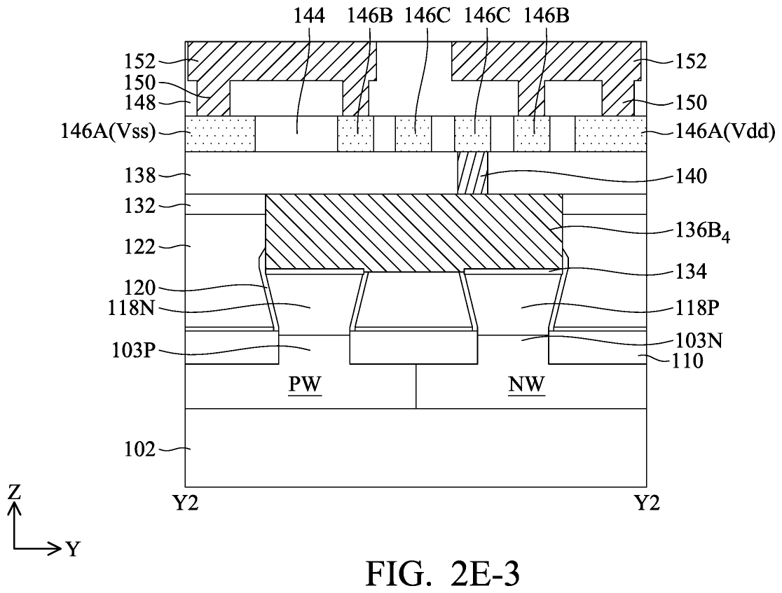

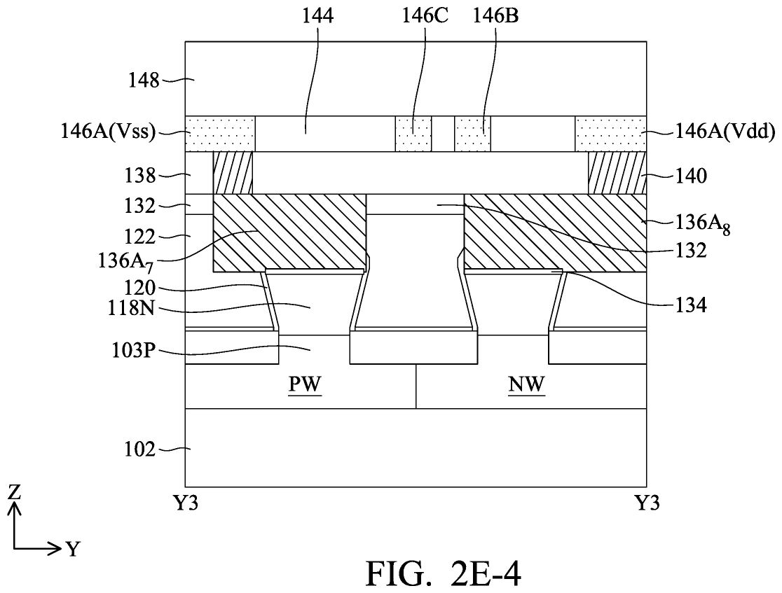

FIGS. 2A to 2E-4 are schematic views illustrating the formation of a semiconductor structure 100 at various intermediate stages, in accordance with some embodiments of the disclosure. FIG. 2A is a plan view (or a layout) of a semiconductor structure 100 after the formation of functional transistors FT1-FT10 and isolation transistors IT1-IT8, in accordance with some embodiments. FIGS. 2A-1, 2A-2 and 2A-3 are cross-sectional views taken along line X1-X1, line Y1-Y1 and Y2-Y2 shown in FIG. 2A, respectively. It should be noted that the plan views in the present disclosure only illustrate some components of the semiconductor structure 100 for illustrative purposes, some other components of the semiconductor structure 100 may be shown in the cross-sectional views.

FIGS. 2A, 2A-1, 2A-2 and 2A-3 illustrate a semiconductor structure 100 which may be nanostructure devices (e.g., GAA FETs), in accordance with some embodiments. The semiconductor structure 100 includes a substrate 102, active regions 104 (including 104A and 104B) over the substrate 102, and final gate stacks 124I (including 124I₁, 124I₄, 124I₆ and 124₉) and final gate stacks 124F (including 124F₂, 124F₃, 124F₅, 124F₇ and 124F₈) across the active regions 104, as shown in FIGS. 2A, 2A-1, 2A-2 and 2A-3, in accordance with some embodiments. The substrate 102 includes a p-type well PW and an n-type well NW, as shown in FIGS. 2A, 2A-1, 2A-2 and 2A-3, in accordance with some embodiments. The p-type well PW and the n-type well NW are immediately arranged in the Y direction, in accordance with some embodiments. The active region 104A is located on the p-type well PW, and the active region 104B is located on the n-type well NW, in accordance with some embodiments. Each of the active regions 104 includes a lower fin element 103P (or 103N) and nanostructures 108 formed over the lower element 103P (or 103N), as shown in FIGS. 2A, 2A-1 and 2A-2, in accordance with some embodiments.

The final gate stacks 124I and 124F wrap around the nanostructures 108 of the active regions 104, in accordance with some embodiments. In some embodiments, the final gate stacks 124I₁, 124I₄, 124I₆ and 124₉ are also referred to as isolation gate stacks, and the final gate stacks 124F₂, 124F₃, 124F₅, 124F₇ and 124F₈ may be also referred to as functional gate stacks. The final gate stacks 1241 and 124F are combined with the nanostructures 108 of the active regions 104 to form nanostructure transistors (including functional transistors FT1-FT10 and isolation transistors IT1-IT8), in accordance with some embodiments. In some embodiments, the functional transistors FT1, FT3, FT5, FT7 and FT9 and the isolation transistors IT1, IT3, IT5 and IT7, which are formed in the p-type well PW, are n-channel transistors. In some embodiments, the functional transistors FT2, FT4, FT6, FT8 and FT10 and the isolation transistors IT2, IT4, IT6 and IT8, formed in the n-type well NW, are p-channel transistors.

In some embodiments, the isolation transistor IT1 is formed at the cross point between the active region 104A and the isolation gate stack 124I₁; the functional transistor FT1 is formed at the cross point between the active region 104A and the functional gate stack 124F₂; the functional transistor FT3 is formed at the cross point between the active region 104A and the functional gate stack 124F₃; the isolation transistor IT3 is formed at the cross point between the active region 104A and the isolation gate stack 124I₄; the functional transistor FT5 is formed at the cross point between the active region 104A and the functional gate stack 124F₅; the isolation transistor IT5 is formed at the cross point between the active region 104A and the isolation gate stack 124I₆; the functional transistor FT7 is formed at the cross point between the active region 104A and the functional gate stack 124F₇; the functional transistor FT9 is formed at the cross point between the active region 104A and the functional gate stack 124F₈ ; and the isolation transistor IT7 is formed at the cross point between the active region 104A and the isolation gate stack 124I₉.

In some embodiments, the isolation transistor IT2 is formed at the cross point between the active region 104B and the isolation gate stack 124I₁; the functional transistor FT2 is formed at the cross point between the active region 104B and the functional gate stack 124F₂; the functional transistor FT4 is formed at the cross point between the active region 104B and the functional gate stack 124F₄; the isolation transistor IT4 is formed at the cross point between the active region 104B and the isolation gate stack 124I₄; the functional transistor FT6 is formed at the cross point between the active region 104B and the functional gate stack 124F₅; the isolation transistor IT6 is formed at the cross point between the active region 104B and the isolation gate stack 124I₆; the functional transistor FT8 is formed at the cross point between the active region 104B and the functional gate stack 124F₇; the functional transistor FT10 is formed at the cross point between the active region 104B and the functional gate stack 124F₈ ; and the isolation transistor IT8 is formed at the cross point between the active region 104B and the isolation gate stack 124I₉.

The semiconductor structure 100 are used to form an integrated circuit which including several functional circuits interconnected with each other, in accordance with some embodiments. Some regions of the substrate 102 (or the semiconductor structure 100) are defined as cell regions C1, C2 and C3, in accordance with some embodiments. Functional circuits are formed in the cell regions C1, C2 and C3, in accordance with some embodiments. The edges (or boundaries) of the cell regions C1, C2 and C3 are dictated as dashed lines. The cell regions C1, C2 and C3 are sequentially arranged in a row (in the X direction), in accordance with some embodiments. In some embodiments, the cell regions C1, C2 and C3 are standard cells and have the same cell height (in the Y direction). The cell regions C1, C2 and C3 may have rectangular shapes in the plan view, and the edges of the cell regions C1, C2 and C3 extend in the X direction and the Y direction, in accordance with some embodiments.

In some embodiments, the edges of the first cell region C1 with respect to the X direction (extending in the Y direction) are aligned with the isolation gate stacks 124I₁ and 124I₄. In some embodiments, the edges of the second cell region C2 with respect to the X direction are aligned with the isolation gate stacks 124I₄ and 124I₆. In some embodiments, the edges of the third cell region C3 are aligned with the isolation gate stacks 124I₆ and 124I₉. In some embodiments, the isolation gate stacks 124I₁, 124I₄, 124I₆ and 124I₉ (and the isolation transistors IT1, IT2, IT3, IT4, ITS, IT6, IT7 and IT8) are configured to prevent leakage between neighboring cell regions.

In some embodiments, the first cell region C1 is a NAND cell where a NAND circuit is to be formed. The circuit in the first cell region C1 includes the functional transistors FT1, FT2, FT3 and FT4, in accordance with some embodiments. In some embodiments, the second cell region C2 is an inverter cell where an inverter circuit is to be formed. The circuit in the second cell region C2 includes the functional transistors FT5 and FT6, in accordance with some embodiments. In some embodiments, the third cell region C3 is a NOR cell where a NOR circuit is to be formed, in accordance with some embodiments. The circuit in the third cell region C3 includes the functional transistors FT7, FT8, FT9 and FT10, in accordance with some embodiments.

The formation of the semiconductor structure 100 of FIGS. 2A, 2A-1, 2A-2 and 2A-3 is described below. The substrate 102 is provided, in accordance with some embodiments. The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

The n-type well NW and the p-type well PW are formed in the substrate 102, in accordance with some embodiments. In some embodiments, the n-type well NW and the p-type well PW have different electrically conductive types. In some embodiments, the wells NW and PW are formed by ion implantation processes. For example, a patterned mask layer (such as a photoresist layer and/or a hard mask layer) is formed to cover regions of the substrate 102 where the p-type well is predetermined to be formed, and then n-type dopants (such as phosphorus or arsenic) are implanted into the substrate 102, thereby forming the n-type well NW, in accordance with some embodiments. Afterward, the patterned mask layer may be removed. Similarly, a patterned mask layer (such as photoresist layer and/or hard mask layer) is formed to cover regions of the substrate 102 where the n-type well is predetermined to be formed, and then p-type dopants (such as boron or BF₂) are implanted into the substrate 102, thereby forming the p-type well PW, in accordance with some embodiments. Afterward, the patterned mask layer may be removed.

In some embodiments, the respective concentrations of the dopants in the wells NW and PW are in a range from about 10¹⁶/cm⁻³ to about 10¹⁸/cm⁻³. In some embodiments, the ion implantation processes may be performed several times with different dosages and different energy intensities. In some embodiments, the ion implantation process may include anti-punch through (APT) implant.

The active regions 104 (including 104A and 104B) are formed over the substrate 102, in accordance with some embodiments. In some embodiments, the active regions 104A and 104B extend in the X direction. That is, the active regions 104A and 104B have longitudinal axes parallel to the X direction, in accordance with some embodiments. The formation of the active regions 104A and 104B includes forming an epitaxial stack over the substrate 102 using an epitaxial growth process, in accordance with some embodiments. The epitaxial stack includes alternating first semiconductor layers 106 (shown in FIG. 1) and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material for the first semiconductor layers 106 has a different lattice constant than the second semiconductor material for the second semiconductor layers 108, in accordance with some embodiments. In some embodiments, the first semiconductor material and the second semiconductor material have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel for the resulting semiconductor devices (such as nanostructure transistors), in accordance with some embodiments.

In some embodiments, the thickness of each of the first semiconductor layers 106 is in a range from about 4 nm to about 20 nm, e.g., about 4 nm to about 10 nm. In some embodiments, the thickness of each of the second semiconductor layers 108 is in a range from about 4 nm to about 20 nm., about 6 nm to about 10 nm. The thickness of the second semiconductor layers 108 may be greater than, equal to, or less than the first semiconductor layers 106, depending on the amount of gate materials to be filled in spaces where the first semiconductor layers 106 are removed. Although three second semiconductor layers 108 are shown in FIGS. 2A-1 and 2A-2, the number is not limited to three, and can be two or four, and is less than 20.

The formation of the active regions 104A and 104B further includes patterning the epitaxial stack and underlying wells PW and NW using photolithography and etching processes, thereby forming trenches and the active regions 104 protruding from between trenches, in accordance with some embodiments. The portion of the p-type well PW protruding from between the trenches serves as the lower fin element 103P of the active region 104A, and the portion of the n-type well NW protruding from between the trenches serves as the lower fin element 103N of the active region 104B, in accordance with some embodiments. A remainder of the epitaxial stack (including the first semiconductor layers 106 and the second semiconductor layers 108) serves as the upper fin elements of the active regions 104A and 104B, in accordance with some embodiments.

In some embodiments, the active regions 104A and 104B are the fin structures 104A and 104B of FIG. 1. In some embodiments, the active regions 104 continuously extend through the cell regions C1, C2 and C3. The active regions 104 may continuously extend through more than three cell regions, e.g., four, five or six cell regions. As a result, the active regions 104 may be referred to as continuous oxide definition (CNOD).

An isolation structure 110 is formed to surround the lower fin elements 103P and 103N of the active regions 104A and 104B, as shown in FIG. 2A-2, in accordance with some embodiments. The isolation structure 110 is configured to electrically isolate active regions the active regions 104 of the semiconductor structure 100 and is also referred to as shallow trench isolation (STI) feature, in accordance with some embodiments. The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active regions 104, in accordance with some embodiments. The planarization may be chemical mechanical polishing (CMP), etching back process, or a combination thereof. The insulating material is then recessed by an etching process (such as dry plasma etching and/or wet chemical etching) until the upper fin elements of the active regions 104 are exposed, in accordance with some embodiments. The recessed insulating material serves as the isolation structure 110, in accordance with some embodiments.

In some embodiments, the semiconductor structure 100 is formed using a gate-late process. For example, dummy gate structures may be formed across the active regions 104 in the place where the final gate stacks 124I and 124F are to be formed. The dummy gate structures are configured as sacrificial structures and will be replaced with the final gate stacks 124I and 124F, in accordance with some embodiments. In some embodiments, the dummy gate structures are the gate structures 112 of FIG. 1. In some embodiments, the dummy gate structures extend in the Y direction. The dummy gate structures surround the channel regions of the active regions 104, in accordance with some embodiments.

Each of the dummy gate structures includes a dummy gate dielectric layer and a dummy gate electrode layer over the dummy gate dielectric layer, in accordance with some embodiments. In some embodiments, the dummy gate dielectric layer is conformally formed along the upper fin elements of the active regions 104. In some embodiments, the dummy gate dielectric layer is made of one or more dielectric materials, such as silicon oxide (SiO), silicon nitride (SiN), silicon oxynitride (SiON), HfO₂, HfZrO, HfSiO, HfTiO, HfAlO. In some embodiments, the dielectric material is deposited using ALD, CVD, thermal oxidation, physical vapor deposition (PVD), another suitable technique, or a combination thereof. In some embodiments, the dummy gate electrode layer is made of semiconductor material such as polysilicon, poly-silicon germanium. In some embodiments, the material for the dummy gate electrode layer is deposited using CVD, ALD, another suitable technique, or a combination thereof. The materials for the dummy gate electrode layer and the dummy gate dielectric layer are patterned into the dummy gate structures using photolithography and etching processes.

Gate spacer layers 114 are formed over the semiconductor structure 100, as shown in FIGS. 2A and 2A-1, in accordance with some embodiments. The gate spacer layers 114 extend along and covers opposite sides of the dummy gate structures, in accordance with some embodiments. In some embodiments, the gate spacer layers 114 are made of a dielectric material, such as silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof, or a combination thereof. In some embodiments, the gate spacer layers 114 are made of low-k dielectric materials. For example, the dielectric constant (k) values of the gate spacer layers 114 may be lower than a k-value of silicon oxide (SiO), such as lower than 4.2, equal to or lower than about 3.9, such as in a range from about 3.5 to about 3.9.

In some embodiments, the formation of the gate spacer layers 114 includes conformally depositing dielectric materials for the gate spacer layer 114 over the semiconductor structure 100 followed by an anisotropic etching process (such as dry plasma etching). In some embodiments, the deposition process includes ALD, CVD (such as PECVD, LPCVD or HARP), another suitable technique, or a combination thereof. Vertical portions of the dielectric material left on the sidewalls of the dummy gate structures serve as the gate spacer layers 114, in accordance with some embodiments.

Source/drain features 118 (including 118N and 118P) are formed over the source/drain regions of the active regions 104, as shown in FIGS. 2A-1 and 2A-2, in accordance with some embodiments. The formation of the source/drain features 118 includes recessing the source/drain regions of the active regions 104 using the dummy gate structures and the gate spacer layers 114 as masks to form source/drain recesses (where the source/drain features 118 are to be formed) on opposite sides of the dummy gate structures, in accordance with some embodiments. The source/drain recesses may extend into the lower fin elements 103N and 103P, in accordance with some embodiments. In some embodiments, the recessing process includes an anisotropic etching process such as dry plasma etching, an isotropic etching process such as dry chemical etching, remote plasma etching or wet chemical etching, or a combination thereof.

Afterward, an etching process is performed to laterally recess, from the source/drain recesses, the first semiconductor layers 106 of the active regions 104, thereby forming notches, and then inner spacer layers 116 are formed in the notches, as shown in FIG. 2A-1, in accordance with some embodiments. The inner spacer layers 116 are formed to abut the recessed side surfaces of the first semiconductor layers 106, in accordance with some embodiments. In some embodiments, the inner spacer layers 116 are located between adjacent second semiconductor layers 108 and between the lowermost second semiconductor layer 108 and the lower fin element 103P (or 103N). In some embodiments, the inner spacer layers 116 extend directly below the gate spacer layers 114, in accordance with some embodiments.

The inner spacer layers 116 may avoid the source/drain features and the gate stack from being in direct contact and are configured to reduce the parasitic capacitance between the gate stack and the source/drain features (i.e., Cgs and Cgd), in accordance with some embodiments. In some embodiments, the inner spacer layers 116 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the inner spacer layers 116 are made of low-k dielectric materials. For example, the dielectric constant (k) values of the inner spacer layers 116 may be lower than a k-value of silicon oxide (SiO), such as lower than 4.2, equal to or lower than about 3.9, such as in a range from about 3.5 to about 3.9.

In some embodiments, the inner spacer layers 116 are formed by depositing a dielectric material for the inner spacer layers 116 over the semiconductor structure 100 to fill the notches, and then etching back the dielectric material to remove the dielectric material outside the notches. Portions of the dielectric material left in the notches serve as the inner spacer layers 116, in accordance with some embodiments. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching or wet chemical etching, or a combination thereof.

Afterward, the source/drain features 118N are formed in the source/drain recesses over the lower fin element 103P of the active region 104P, and the source/drain features 118P are formed in the source/drain recesses over the lower fin element 103N of the active regions 104N, as shown in FIGS. 2A-1 and 2A-3, in accordance with some embodiments. The source/drain features 118N and 118P are formed on opposite sides of the dummy gate structures, in accordance with some embodiments. In some embodiments, the source/drain features 118N have a different electrically conductive type than the source/drain features 118P. The formation may include one or more epitaxial growth processes. These epitaxial growth processes may be MBE, MOCVD, or VPE, another suitable technique, or a combination thereof.

In some embodiments, the source/drain features 118N and the source/drain features 118NP may be formed separately. For example, a patterned mask layer (such as photoresist layer and/or hard mask layer) may be formed to cover the semiconductor structure 100 over the n-type well NW, and then the source/drain features 118N are grown. Afterward, the patterned mask layer may be removed. Similarly, a patterned mask layer (such as photoresist layer and/or hard mask layer) is formed to cover the semiconductor structure 100 over the p-type well PW, and then the source/drain features 118P are grown. Afterward, the patterned mask layer may be removed.

In some embodiments, the source/drain features 118N and 118P are in-situ doped during the epitaxial processes. In some embodiments, the source/drain features 118N are doped with the n-type dopant during the epitaxial growth process. For example, the n-type dopant may be phosphorous (P) or arsenic (As). For example, the n-type source/drain features 118N may be the epitaxially grown silicon phosphorous (SiP), silicon carbon (SiC), silicon arsenic (SiAs), silicon (Si) or a combination thereof doped with phosphorous and/or arsenic. In some embodiments, the concentrations of the dopant (e.g., P) in the source/drain features 118N are in a range from about 2×10¹⁹ cm⁻³ to about 3×10²¹ cm⁻³.

In some embodiments, the source/drain features 118P are doped with the p-type dopant during the epitaxial growth process. For example, the p-type dopant may be boron (B) or BF₂. For example, the p-type source/drain features 118P may be the epitaxially grown silicon germanium (SiGe), silicon germanium carbon (SiGeC), germanium (Ge) or a combination thereof doped with boron (B). In some embodiments, the concentrations of the dopant (e.g., B) in the source/drain features 118P are in a range from about 1×10¹⁹ cm⁻³ to about 6×10²⁰ cm⁻³. In some embodiments, the n-type source/drain features 118P and the p-type source/drain features 118P are made of different epitaxial materials. For example, the n-type source/drain features 118N are made of SiP, and the p-type source/drain features 118P are made of SiGe.

A contact etching stop layer (CESL) 120 is formed over the semiconductor structure 100 to cover the source/drain features 118N and 118P, as shown in FIGS. 2A-1 and 2A-3, in accordance with some embodiments. In some embodiments, the contact etching stop layer 120 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, a dielectric material for the contact etching stop layer 120 is globally and conformally deposited over the semiconductor structure 100 using CVD (such as LPCVD, PECVD, HDP-CVD, or HARP), ALD, another suitable method, or a combination thereof.

Afterward, a first interlayer dielectric layer 122 is formed over the contact etching stop layer 120, as shown in FIGS. 2A-1 and 2A-3 in accordance with some embodiments. In some embodiments, the first interlayer dielectric layer 122 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the first interlayer dielectric layer 122 and the contact etching stop layer 120 are made of different materials and have a great difference in etching selectivity. In some embodiments, the dielectric material for the first interlayer dielectric layer 122 is deposited using such as CVD (such as HDP-CVD, PECVD, HARP or FCVD), another suitable technique, or a combination thereof. The dielectric materials for the contact etching stop layer 120 and the first interlayer dielectric layer 122 above the upper surface of the dummy gate electrode layer are removed using such as CMP, in accordance with some embodiments.

One or more etching processes are performed to remove the dummy gate structures to form gate trenches and remove the first semiconductor layers 106 of the active regions 104 to form gaps, in accordance with some embodiments. In some embodiments, the gate trenches expose the inner sidewalls of the gate spacer layers 114 facing the channel region, in accordance with some embodiments. In some embodiments, the gaps expose the inner sidewalls of the inner spacer layers 116 facing the channel region. The one or more etching processes may include an anisotropic etching process such as dry plasma etching, an isotropic etching process such as dry chemical etching, remote plasma etching or wet chemical etching, or a combination thereof.

After the one or more etching processes, the four main surfaces of the second semiconductor layers 108 are exposed, in accordance with some embodiments. The exposed second semiconductor layers 108 of each of the active regions 104 form nine sets of nanostructures 108, in accordance with some embodiments. Each set includes three nanostructures 108 vertically stacked and spaced apart from one other, in accordance with some embodiments. As the term is used herein, “nanostructures” refers to the semiconductor layers with cylindrical shape, bar shaped and/or sheet shape. The nanostructures 108 function as channel layers of the resulting semiconductor devices (e.g., nanostructure transistors such as GAA transistors), in accordance with some embodiments.

The final gate stacks 124I and 124F are formed in the gate trenches and gaps, thereby wrapping around the nanostructures 108, as shown in FIGS. 2A, 2A-1 and 2A-2, in accordance with some embodiments. In some embodiments, the final gate stacks 124I and 124F extend in the Y direction. That is, the final gate stacks 124I and 124F have longitudinal axes parallel to the Y direction, in accordance with some embodiments. The final gate stacks 124I and 124F engage the channel region so that current can flow between the source/drain regions during operation. In some embodiments, each of the final gate stacks 124I and 124F includes a gate dielectric layer 126 and a metal gate electrode layer 128 (including 128N and 128P) formed over the gate dielectric layer 126, as shown in FIGS. 2A-1 and 2A-2, in accordance with some embodiments.

The gate dielectric layer 126 is formed to partially fill the gate trenches and the gaps, in accordance with some embodiments. In some embodiments, the gate dielectric layer 126 may include an interfacial layer and a high-k dielectric layer formed over the interfacial layer. The interfacial layer may be made of silicon oxide or nitrogen-doped silicon oxide. In some embodiments, the high-k dielectric layer is dielectric material with high dielectric constant (k value), for example, greater than 3.9. In some embodiments, the high-k dielectric layer includes hafnium oxide (HfO₂), TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), a combination thereof, or another suitable material. The high-k dielectric layer may be deposited using ALD, PVD, CVD, and/or another suitable technique.

The metal gate electrode layer 128 (including 128N and 128P) is formed to fill remainders of the gate trenches and the gaps, in accordance with some embodiments. The metal gate electrode layer 128N is formed over the p-type well PW, and the metal gate electrode layer 128P is formed over the n-type well NW, in accordance with some embodiments. In some embodiments, the metal gate electrode layer 128 is made of more than one conductive material, such as a metal, metal alloy, conductive metal oxide and/or metal nitride, another suitable conductive material, or a combination thereof. For example, the metal gate electrode layer 128 may be made of TiN, TaN, TiAl, TiAlN, TaAl, TaAlN, TaAlC, TaCN, WNC, Co, Pt, W, Ti, Ag, Al, TaC, TaSiN, Mn, Zr, Ru, Mo, WN, Cu, W, Re, Ir, Ni, another suitable conductive material, or multilayers thereof.

The metal gate electrode layer 128 may be a multi-layer structure with various combinations of a diffusion barrier layer, work function layers with a selected work function to enhance the device performance (e.g., threshold voltage) for n-channel FETs or p-channel FETs, a capping layer to prevent oxidation of work function layers, a glue layer to adhere work function layers to a next layer, and a metal fill layer to reduce the total resistance of gate stacks, and/or another suitable layer. The metal gate electrode layer 128 may be formed using ALD, PVD, CVD, e-beam evaporation, or another suitable technique.

The metal gate electrode layers 128N and 128P may be formed separately for n-channel nanostructure transistors and p-channel nanostructure transistors, which may use different work function materials. For example, a patterned mask layer (such as a photoresist layer and/or a hard mask layer) is formed to cover regions of the substrate 102 over the p-type well PW, and the conductive materials for the metal gate electrode layer 128P are deposited, in accordance with some embodiments. Afterward, the patterned mask layer may be removed. Similarly, a patterned mask layer (such as photoresist layer and/or hard mask layer) is formed to cover regions of the substrate 102 over the n-type well NW, and the conductive materials for the metal gate electrode layer 128N are deposited, in accordance with some embodiments. Afterward, the patterned mask layer may be removed. In alternative embodiments, the conductive material for the metal gate electrode layers 128N is the same as the conductive material for the metal gate electrode layers 128P.

A planarization process such as CMP may be performed on the semiconductor structure 100 to remove the materials of the gate dielectric layer 126 and the metal gate electrode layer 128 formed above the upper surface of the first interlayer dielectric layer 122, in accordance with some embodiments. The final gate stacks 124I and 124F wrapping around the nanostructures 108 of the active region 104 combine with the neighboring source/drain features 118 to form nanostructure transistors IT1-IT8 and FT1-FT10. In some embodiments, the neighboring transistors share a common source/drain feature 118.

The lengths (i.e., gate lengths) of the final gate stacks 124I and 124F in the X direction may have the smallest critical dimension (CD) in the semiconductor manufacturing process. The circuits in the cell regions C1, C2, C3 are formed from the active regions 104 with CNOD design and separated from one other by the isolation gate stack 125I instead of another isolation features, which may facilitate to improve the circuit density.

FIG. 2B is a plan view (or a layout) of a semiconductor structure 100 after the formation of gate isolation structures 130, in accordance with some embodiments. FIGS. 2B-1, 2B-2 and 2B-3 are cross-sectional views taken along line X1-X1, line Y1-Y1 and Y2-Y2 shown in FIG. 2B, respectively.

Gate isolation structures 130 are formed in and/or through the final gate stacks 124I and 124F and the gate spacer layers 114 and land on the isolation structure 110, as shown in FIGS. 2B and 2B-2, in accordance with some embodiments. The gate isolation structures 130 are located on the edges (or the boundaries) of the cells C1, C2 and C3, in accordance with some embodiments. Specifically, at the edges of the cells C1, C2 and C3 with respect to the Y direction (extending in the X direction), the gate isolation structures 130 are disposed corresponding to each of the final gate stacks 124I and 124F, in accordance with some embodiments. At the edges of the cells C1, C2 and C3 with respect to the X direction, the gate isolation structures 130 are disposed corresponding to the isolation gate stacks 124I on the boundary between the p-well PW and the n-well NW (or the boundary between the metal gate electrode layers 128N and 128P), in accordance with some embodiments.

The isolation gate stacks 124I are cut through by the gate isolation structures 130 into several segments 125I (including 125I₁, 125I₂, 124I₅, 125I₆, 125I₈, 125I₉, 125I₁₂ and 125I₁₃), in accordance with some embodiments. The isolation gate stack 125I₁ is electrically isolated from the isolation gate stack 125I₂. The isolation gate stack 125I₅ is electrically isolated from the isolation gate stack 125I₆. The isolation gate stack 125I₈ is electrically isolated from the isolation gate stack 125I 9 . The isolation gate stack 125I₁₂ is electrically isolated from the isolation gate stack 125I₁₃, in accordance with some embodiments. In some embodiments, the isolation gate stacks 125I are electrically connected to subsequently formed power supply lines. The functional gate stacks 124F are cut through by the gate isolation structures 130 into several segments 125F (including 125F₃, 125F₄, 125F₇, 125F₁₀ and 125F₁₁), in accordance with some embodiments. In some embodiments, the functional gate stacks 125F are electrically connected to subsequently formed signal lines.

The formation of the gate isolation structures 130 includes patterning the final gate stacks 124I and 124F and the gate spacer layers 114 to form gate-cut openings (where the gate isolation structures 130 are to be formed) using photolithography and etching processes until the isolation structure 110 is exposed. The etch processes may include dry etching such as reactive ion etch (RIE), neutral beam etch (NBE), inductive coupled plasma (ICP) etch, capacitively coupled plasma (CCP) etch, another suitable method, or a combination thereof. The formation of the gate isolation structures 130 further includes depositing a dielectric material for the gate isolation structures 130 to overfill the gate-cut opening, in accordance with some embodiments. The gate isolation structures 130 are made of dielectric material such as silicon nitride (SiN), silicon oxynitride (SiON), silicon carbon nitride (SiCN), silicon oxycarbonitride (SiOCN), oxygen-doped silicon carbonitride (Si(O)CN), silicon oxide (SiO₂), or a combination thereof. In some embodiments, the gate isolation structures 130 include dielectric material with k-value greater than 9, such as LaO, AlO, AlON, ZrO, HfO, ZnO, ZrN, ZrAlO, TiO, TaO, YO, and/or TaCN. In some embodiments, the deposition process is ALD, CVD (such as LPCVD, PECVD, HDP-CVD, or HARP), another suitable technique, or a combination thereof. Afterward, a planarization process is then performed on the dielectric material for the gate isolation structures 130 until the first interlayer dielectric layer 122 is exposed, in accordance with some embodiments. The planarization may be CMP, etching back process, or a combination thereof.

The formation of the semiconductor structure 100 further includes forming a multilayer interconnect structure over the substrate 102, in accordance with some embodiments. The multilayer interconnect structure electrically couples various devices (for example, transistors, resistors, capacitors, and/or inductors) and/or components of devices (such as the source/drain features 118N and 118P and/or the final gate stacks 125I and 125F), in accordance with some embodiments. In some embodiments, the multilayer interconnect structure typically includes a combination of dielectric layers and electrically conductive features formed in the dielectric layers. The conductive features are configured to form vertical interconnect features (providing, for example, vertical connection between features and/or vertical electrical routing), such as contact plugs and/or vias, and/or horizontal interconnect features (providing, for example, horizontal electrical routing), such as metal layers, in accordance with some embodiments. Vertical conductive features of a multilayer interconnect structure typically connect horizontal conductive features in different layers (or different planes) of the multilayer interconnect structure, in accordance with some embodiments. The formation and the configuration of a multilayer interconnect structure is described in detail below.

FIG. 2C is a plan view (or a layout) of a semiconductor structure 100 after the formation of a second interlayer dielectric layer 132 and contact plugs 136A (including 136A₁₋₈) and contact plugs 136B (including 136B₁₋₇), in accordance with some embodiments. FIGS. 2C-1, 2C-2, 2C-3 and 2C-4 are cross-sectional views taken along line X1-X1, line Y1-Y1, Y2-Y2 and Y3-Y3 shown in FIG. 2C, respectively.

A second interlayer dielectric layer 132 is formed over the semiconductor structure 100, as shown in FIGS. 2C-1, 2C-2, 2C-3 and 2C-4, in accordance with some embodiments. In some embodiments, the second interlayer dielectric layer 132 is made of dielectric material, such as USG, BPSG, FSG, PSG, BSG, and/or another suitable dielectric material. In some embodiments, the second interlayer dielectric layer 132 is deposited using such as CVD (such as HDP-CVD, PECVD, HARP or FCVD), another suitable technique, or a combination thereof.

Contact plugs 136A and 136B are formed in and/or through the second interlayer dielectric layer 132, the first interlayer dielectric layer 122 and the contact etching stop layer 120 and land on and are electrically connected to the source/drain features 118N and 118P, as shown in FIGS. 2C, 2C-1, 2C-3 and 2C-4, in accordance with some embodiments. In some embodiments, the contact plugs 136A (including 136A₁₋₈) land on the source terminals of the transistors IT and FT and may be also referred to as source contact plugs. In some embodiments, the contact plugs 136A are electrically connected to subsequently formed power supply lines. In some embodiments, the contact plugs 136B (including 136B₁₋₇) land on the drain terminals of the transistors IT and FT and may be also referred to as drain contact plugs. In some embodiments, the contact plugs 136B are electrically connected to subsequently formed signal lines.

In some embodiments, the contact plugs 136A are disposed adjacent to the edges of the cells C1, C2 and C3 with respect to the X direction. In some embodiments, the contact plugs 136A are disposed between the isolation transistors IT and the functional transistors FT (or between the isolation gate stacks 125I and the functional gate stacks 125F). Specifically, the contact plugs 136A₁ are located between the isolation gate stack 125I₁ and the functional gate stack 125F₃ and on the source terminal shared by the isolation transistors IT1 and the functional transistors FT1. The contact plugs 136A₂ are located between the isolation gate stack 125I₂ and the functional gate stack 125F₃ and on the source terminal shared by the isolation transistors IT2 and the functional transistors FT2. The contact plugs 136A₃ are located between the isolation gate stack 125I₆ and the functional gate stack 125F₄ and on the source terminal shared by the isolation transistors IT4 and the functional transistors FT4. The contact plugs 136A₄ are located between the isolation gate stack 125I₈ and the functional gate stack 125I₇ and on the source terminal shared by the isolation transistors ITS and the functional transistors FTS. The contact plugs 136A₅ are located between the isolation gate stack 125I₉ and the functional gate stack 125F₇ and on the source terminal shared by the isolation transistors IT6 and the functional transistors FT6. The contact plugs 136A₆ are located between the isolation gate stack 125I₈ and the functional gate stack 125F₁₀ and on the source terminal shared by the isolation transistors IT5 and the functional transistors FT7. The contact plugs 136A₇ are located between the isolation gate stack 125I₁₂ and the functional gate stack 125F₁₁ on the source terminal shared by the isolation transistors IT7 and the functional transistors FT9. The contact plugs 136A₈ are located between the isolation gate stack 125I₁₃ and the functional gate stack 125F₁₁ and on the source terminal shared by the isolation transistors IT8 and the functional transistors FT10, in accordance with some embodiments.

In some embodiments, some of the contact plugs 136B are disposed between the functional transistors FT (or between the functional gate stacks 125F). Specifically, the contact plug 136B₁ is located between the functional gate stacks 125F₃ and 125F₄ and on the drain terminal shared by the functional transistors FT1 and the functional transistors FT3. The contact plug 126B₂ is located between the functional gate stacks 125F₃ and 125F₄ and on the drain terminal shared by the functional transistors FT2 and the functional transistors FT4. The contact plug 136B₆ is located between the functional gate stacks 125F₁₀ and 125F₁₁ and on the drain terminal shared by the functional transistors FT7 and the functional transistors FT9. The contact plug 126B₇ is located between the functional gate stacks 125F₁₀ and 125F₁₁ and on the drain terminal shared by the functional transistors FT8 and the functional transistors FT10, in accordance with some embodiments.

In some embodiments, some other contact plugs 136B are disposed between the isolation transistors IT and the functional transistors FT (or between the isolation gate stacks 125I and the functional gate stacks 125F). Specifically, the contact plugs 136B₃ are located between the isolation gate stack 125I₅ and the functional gate stack 125F₄ and on the drain terminal shared by the isolation transistors IT3 and the functional transistors FT3. The contact plugs 136B₄ are located between the isolation gate stack 125I₅ (or the functional gate stack 125I₆) and the functional gate stack 125F₇ and on the drain terminal shared by the isolation transistors IT3 and the functional transistors FT5 and on the drain terminal shared by the isolation transistors IT4 and the functional transistors FT6. The contact plugs 136B₅ are located between the isolation gate stack 125I₉ and the functional gate stack 125F₁₀ and on the drain terminal shared by the isolation transistors IT6 and the functional transistors FT8.

In some embodiments, the contact plugs 136A extend to the edges of the cells C1, C2 and C3 with respect to the Y direction. In some embodiments, the contact plugs 136A may extend beyond the edges of the cells C1, C2 and C3 with respect to the Y direction and into other cell regions. In some embodiments, the contact plugs 136B are disposed within the cells C1, C2 and C3 and do not extend to the edges of the cells C1, C2 and C3. In some embodiments, the lengths in the Y direction of the contact plugs 136A are greater than the lengths in the Y direction of the contact plugs 136B except for the contact plug 136B₄ which lands on two source/drain features.

In some embodiments, the contact plugs 136A₁-136A₈ have widths W1 in the X direction. In some embodiments, the widths W1 of the contact plugs 136A₁-136A₈ are in a range from about 6 nm to about 30 nm. In some embodiments, the contact plugs 136B₁-136B₇ have widths W2 in the X direction. In some embodiments, the width W2 of the contact plugs 136B₁-136B₇ are in a range from about 5.5 nm to about 29.5 nm. In some embodiments, the contact plugs 136A₁-136A₈ are wider than the contact plugs 136B₁-136B₇ (i.e., W1>W2). In some embodiments, the widths W1 are greater than the widths W2 by about 0.5 nm to about 5 nm such as 0.5 nm to 2 nm. In some embodiments, the ratio (W1/W2) of the widths W1 to the widths W2 is in a range from about 1.05 to about 1.25.

In some embodiments, the contact plugs 136A are offset toward the isolation gate stacks 125I. That is, the contact plugs 136A are closer to the isolation gate stacks 125I than to the functional gate stacks 125F, in accordance with some embodiments. In some embodiments, the contact plug 136A (e.g., 136A₂) is spaced a distance of D1 apart from the neighboring isolation gate stack 125I (e.g., 125I₂) and a distance of D2 apart from the neighboring functional gate stack 125F (e.g., 125F₃), in accordance with some embodiments. Distance D2 is greater than distance D11. In some embodiments, the contact plugs 136B are disposed in the middle of two adjacent final gate stacks (125I and/or 125F) and are spaced apart from the two final gate stacks (125I and/or 125F) by substantially the same distance D2.

Because both the contact plugs 136A and the isolation gate stacks 125I are electrically connected to the power supply lines, the contact plugs 136A and the isolation gate stacks 125I have the same voltage (i.e., zero voltage difference). As a result, reducing the distance between contact plugs 136A (source contact plug) and the isolation gate stacks 125I (by enlarging the widths of the contact plugs toward the isolation gate stacks) may not negatively impact the contact-to-gate isolation margin because the leakage (or breakdown) between the contact plugs 136A and the isolation gate stacks 125I and the capacitance between the contact plugs 136A and the isolation gate stacks 125I are not of concern. The source contact plugs 136A with the greater width W1 may reduce the resistance (e.g., contact resistance Rc and/or sheet resistance Rs), and the drain contact plugs 136B with the less width W2 may reduce the risk of the leak (or breakdown) between the contact plugs 136B and the final gate stacks 125I or 125F and/or capacitance between the contact plugs 136B and the final gate stacks 125I or 125F, in accordance with some embodiments. Therefore, the performance and the reliability of the resulting semiconductor devices may be enhanced.

If the ratio (W1/W2 or the width W1) is too small, the resistance of the contact plugs 136A may be not sufficiently reduced, in accordance with s. If the ratio (W1/W2 or the width W1) is too large, the risk of the leak (or breakdown) between the contact plugs 136A and the functional gate stacks 125F and/or capacitance between the contact plugs 136A and the functional gate stacks 125F may be increased.

In some embodiments, the formation of the contact plugs 136A and 136B includes patterning the second interlayer dielectric layer 132, the first interlayer dielectric layer 122 and the contact etching stop layer 120 to form contact openings (where the contact plugs 136A and 136B are to be formed) using photolithography and etching processes until the source/drain features 118 are exposed. The etch processes may include dry etching such as RIE, NBE, ICP etch, CCP etch, another suitable method, or a combination thereof. A silicide layer 134 (such as WSi, NiSi, TiSi and/or CoSi) is formed on the exposed source/drain features 118, and then one or more conductive materials for the contact plugs 136 are deposited to fill the contact openings, in accordance with some embodiments. In some embodiments, one or more conductive materials are deposited using CVD, PVD, e-beam evaporation, ALD, electroplating (ECP), electroless deposition (ELD), another suitable method, or a combination thereof to overfill the contact openings. Afterward, the one or more conductive materials over the upper surface of the second interlayer dielectric layer 132 are planarized using, for example, CMP. After the planarization process, the upper surfaces of the contact plugs 136A and 136B, and the upper surface of the second interlayer dielectric layer 132 are substantially coplanar, in accordance with some embodiments.

In some embodiments, the contact plugs 136A pass through and are in contact with the portions of the contact etching stop layer 120 along the sidewalls of the isolation gate stacks 125I, while the contact plugs 136A are separated from the portions of the contact etching stop layer 120 along the sidewalls of the functional gate stacks 125F by the first interlayer dielectric layer 122.

The contact plugs 136 may have a multilayer structure including, for example, liner layers, glue layers, barrier layers, seed layers, metal bulk layers, another suitable layer, or a combination thereof. For example, a barrier layer (not shown) may optionally be deposited along the sidewalls and the bottom surfaces of the contact openings. The barrier layer is used to prevent the metal from the subsequently formed metal material from diffusing into the dielectric material (e.g., the second interlayer dielectric layer 132, the first interlayer dielectric layer 122 and the contact etching stop layer 120). The barrier layer may be made of tantalum (Ta), tantalum nitride (TaN), titanium (Ti), titanium nitride (TiN), cobalt tungsten (CoW), another suitable material, or a combination thereof. If the subsequently formed metal material does not easily diffuse into the dielectric material, the barrier layer may be omitted.

A glue layer (not shown) may optionally be deposited along the sidewalls and the bottom surfaces of the contact openings, and on the barrier layer (if formed). The glue layer is used to improve adhesion between the subsequently formed metal material and the dielectric material (e.g., the second interlayer dielectric layer 132, the first interlayer dielectric layer 122 and the contact etching stop layer 120). The glue layer may be made of tantalum nitride (TaN), titanium (Ti), titanium nitride (TiN), another suitable material, or a combination thereof.

A metal bulk layer is then deposited on the glue layer (if formed) to fill the remainder of the contact openings. In some embodiments, the metal bulk layer is formed using a selective deposition technique such as cyclic CVD process or ELD process, and it is not necessary to form a glue layer in the contact openings before depositing the metal bulk material. In some embodiments, the metal bulk layer is made of one or more conductive materials with low resistance and good gap-fill ability, for example, cobalt (Co), nickel (Ni), tungsten (W), titanium (Ti), tantalum (Ta), copper (Cu), rhodium (Rh), iridium (Ir), platinum (Pt), aluminum (Al), ruthenium (Ru), molybdenum (Mo), another suitable metal material, or a combination thereof.

FIG. 2D is a plan view (or a layout) of a semiconductor structure 100 after the formation of a third interlayer dielectric layer 132, vias 140 and 142, a first intermetal dielectric (IMD) layer 144, and a first metal layer (M1), in accordance with some embodiments. FIGS. 2D-1, 2D-2, 2D-3 and 2D-4 are cross-sectional views taken along line X1-X1, line Y1-Y1, Y2-Y2 and Y3-Y3 shown in FIG. 2D, respectively.

A third interlayer dielectric layer 138 is formed over the semiconductor structure 100, as shown in FIGS. 2D-1, 2D-2, 2D-3 and 2D-4, in accordance with some embodiments. In some embodiments, the third interlayer dielectric layer 138 is made of dielectric material, such as USG, BPSG, FSG, PSG, BSG, and/or another suitable dielectric material. In some embodiments, the third interlayer dielectric layer 138 is deposited using such as CVD (such as HDP-CVD, PECVD, HARP or FCVD), another suitable technique, or a combination thereof.

Vias 140 are formed in and/or through the third interlayer dielectric layer 138 and vias 142 are formed in and/or through the third interlayer dielectric layer 138 and the second interlayer dielectric layer 132, as shown in FIGS. 2D, 2D-1, 2D-3 and 2D-4, in accordance with some embodiments. The vias 140 land on and are electrically connected to contact plugs 136A and 136B and may be also referred to as source/drain vias (VS or VD), in accordance with some embodiments. The vias 142 land on and are electrically connected to the metal gate electrodes 128 of the final gate stacks 125I and 125F and may be also referred to as gate vias (VG), in accordance with some embodiments.

In some embodiments, the formation of the vias 140 and via 142 includes patterning the third interlayer dielectric layer 138 and the second interlayer dielectric layer 132 to form via openings (where the vias 140 and via 142 are to be formed) using photolithography and etching processes. In some embodiments, the final gate stacks 125I and 125F are exposed from the via openings for vias 142, and the contact plugs 136A and 136B are exposed from the via openings for vias 140. The etch processes may include dry etching such as RIE, NBE, ICP etch, CCP etch, another suitable method, or a combination thereof. The patterning processes for the vias 140 and via 142 may be formed separately. In some embodiments, one or more conductive materials are deposited using CVD, PVD, e-beam evaporation, ALD, ECP, ELD, another suitable method, or a combination thereof to overfill the via openings. Afterward, the one or more conductive materials over the upper surface of the third interlayer dielectric layer 138 are planarized using, for example, CMP. After the planarization process, the upper surfaces of the vias 140, the vias 142, the upper surface of the third interlayer dielectric layer 138 are substantially coplanar, in accordance with some embodiments.

The vias 140 and via 142 may have a multilayer structure. For example, a barrier layer (not shown) may optionally be deposited along the sidewalls and the bottom surfaces of the via openings. The barrier layer may be made of tantalum (Ta), tantalum nitride (TaN), titanium (Ti), titanium nitride (TiN), cobalt tungsten (CoW), another suitable material, or a combination thereof. A glue layer (not shown) may optionally be deposited along the sidewalls and the bottom surfaces of the via openings, and on the barrier layer (if formed). The glue layer may be made of tantalum nitride (TaN), titanium (Ti), titanium nitride (TiN), another suitable material, or a combination thereof. A metal bulk layer is then deposited on the glue layer (if formed) to fill the remainder of the via openings. In some embodiments, the metal bulk layers are made of one or more conductive materials, such as cobalt (Co), nickel (Ni), tungsten (W), titanium (Ti), tantalum (Ta), copper (Cu), aluminum (Al), ruthenium (Ru), molybdenum (Mo), another suitable metal material, or a combination thereof.

A first intermetal dielectric layer 144 is formed over the vias 140 and 142 and the third interlayer dielectric layer 138, as shown in FIGS. 2D-1, 2D-2, 2D-3 and 2D-4, in accordance with some embodiments. In some embodiments, the first intermetal dielectric layer 144 is made of one or more dielectric materials, such as silicon oxide (SiO), silicon nitride (SiN), silicon oxynitride (SiON), silicon carbide (SiC), aluminum oxide (Al₂O₃), dielectric material(s) with low dielectric constant (low-k) such as SiCOH, SiOCN, and/or SiOC, or a combination thereof. In some embodiments, the first intermetal dielectric layer 144 is made of an extreme low-k (ELK) dielectric material with a dielectric constant (k) less than about 3.0, or even less than about 2.5. In some embodiments, ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon oxide (SiO₂). In some embodiments, the first intermetal dielectric layer 144 is formed using CVD (such as LPCVD, HARP, and FCVD), ALD, spin-on coating, another suitable method, or a combination thereof. A post-curing process (e.g., UV curing) may be performed on the as-deposited ELK dielectric material for the first intermetal dielectric layer 144 to form a porous structure.

A first metal layer (M1) is formed in and/or through the first intermetal dielectric layer 144, in accordance with some embodiments. The first metal layer (M1) includes several lines (tracks) e.g., power supply lines 146A, power branch lines 146B and signal lines 146C, as shown in FIGS. 2D, 2D-1, 2D-2, 2D-3 and 2D-4, in accordance with some embodiments. The power supply lines 146A include a Vdd power rail providing positive voltage and a Vss power rail which may be an electrical ground, in accordance with some embodiments. The power branch lines 146B are electrically connected to the power supply lines 146A through an above metal layer (e.g., M2). The signal lines 146C are configured for signal transmission and are electrically isolated from the power supply lines 146A and the power branch lines 146B, in accordance with some embodiments.

The lines 146A, 146B and 146C extend in the X direction. That is, the lines 146A, 146B and 146C have longitudinal axes parallel to the X direction, in accordance with some embodiments. The power supply lines 146A extend along and overlap the edges of the cells C1, C2 and C3 with respect to the Y direction, in accordance with some embodiments. The Vss power rail is electrically connected to the source terminals of the n-channel transistors IT1, FT1, FT5, ITS, FT7, FT9 and IT7 through the vias 140 and the contact plugs 136A, in accordance with some embodiments. The Vdd power rail is electrically connected to the source terminals of the p-channel transistors IT2, FT2, FT4, IT4, FT6, IT6, FT10 and IT8 through the vias 140 and the contact plugs 136A, in accordance with some embodiments.

The power branch lines 142B and the signal lines 142C are located between the power supply lines 146A, in accordance with some embodiments. The power branch lines 142B are electrically connected to the isolation gate stacks 125I of the isolation transistors IT, in accordance with some embodiments. In some embodiments, the power supply lines 142B may continuously extend through the edges of the cells C1, C2 or C3 to connect two isolation gate stacks 125I (e.g., 125I₂ and 125I₆, 125I₅ and 125I₈, or 125I₉ and 125I₁₃). The signal lines 142C are electrically connected to the functional gate stacks 125F of the functional transistors FT and the drain terminals of the transistors FT, in accordance with some embodiments.

In some embodiments, the formation of the first metal layer (M1) includes patterning the first intermetal dielectric layer 144 using photolithography and etching processes to form trenches (where the first metal layer (M1) is to be formed) through the first intermetal dielectric layer 144 and exposing the vias 140 and 142. The etch processes may include dry etching such as RIE, NBE, ICP etch, CCP etch, another suitable method, or a combination thereof. One or more conductive materials for the first metal layer (M1) are then deposited using CVD, PVD, e-beam evaporation, ALD, ECP, ELD, another suitable method to overfill the trenches. Afterward, a planarization process such as CMP and/or an etching back process is performed to remove an excess portion of the conductive materials from the upper surface of the first intermetal dielectric layer 144. After the planarization process, the upper surfaces of the first metal layer (M1) and the first intermetal dielectric layer 144 are substantially coplanar, in accordance with some embodiments.

The first metal layer M1 may have a multilayer structure. For example, a barrier layer (not shown) may optionally be deposited along the sidewalls and the bottom surfaces of the trenches. The barrier layer may be made of tantalum (Ta), tantalum nitride (TaN), titanium (Ti), titanium nitride (TiN), cobalt tungsten (CoW), another suitable material, or a combination thereof. A glue layer (not shown) may optionally be deposited along the sidewalls and the bottom surfaces of the trenches, and on the barrier layer (if formed). The glue layer may be made of tantalum nitride (TaN), titanium (Ti), titanium nitride (TiN), another suitable material, or a combination thereof. A metal bulk layer is then deposited on the glue layer (if formed) to fill the remainder of the trenches. In some embodiments, the metal bulk layers are made of one or more conductive materials, such as copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), golden (Au), aluminum (Al), another suitable metal material, or a combination thereof.

FIG. 2E is a plan view (or a layout) of a semiconductor structure 100 after the formation of a second intermetal dielectric layer 148, vias 150 and a second metal layer (M2), in accordance with some embodiments. FIGS. 2E-1, 2E-2, 2E-3 and 2E-4 are cross-sectional views taken along line X1-X1, line Y1-Y1, Y2-Y2 and Y3-Y3 shown in FIG. 2E, respectively.

A second intermetal dielectric layer 148 is formed over the first metal layer (M1) and the first intermetal dielectric 144, as shown in FIGS. 2E-1, 2E-2, 2E-3 and 2E-4, in accordance with some embodiments. In some embodiments, the second intermetal dielectric layer 148 is made of one or more dielectric materials, such as silicon oxide (SiO), silicon nitride (SiN), silicon oxynitride (SiON), silicon carbide (SiC), aluminum oxide (Al₂O₃), dielectric material(s) with low dielectric constant (low-k) such as SiCOH, SiOCN, and/or SiOC, or a combination thereof. In some embodiments, the second intermetal dielectric layer 148 is made of ELK dielectric material with a dielectric constant (k) less than about 3.0, or even less than about 2.5. In some embodiments, the second intermetal dielectric layer 148 is formed using CVD (such as LPCVD, HARP, and FCVD), ALD, spin-on coating, another suitable method, or a combination thereof. A post-curing process (e.g., UV curing) may be performed on the as-deposited ELK dielectric material for the second intermetal dielectric layer 148 to form a porous structure.

Vias 150 are formed in and/or through the second intermetal dielectric layer 148 and land on the first metal layer M1 (e.g., on the power supply lines 142A and the power branch lines 142B), as shown in FIGS. 2E, 2E-1 and 2E-3, in accordance with some embodiments. The second metal layer (M2) is formed in and/or through the second intermetal dielectric layer 148 and on the vias 150, in accordance with some embodiments. The second metal layer (M2) includes several lines (tracks), e.g., conductive lines 152, as shown in FIGS. 2E, 2E-1, 2E-3 and 2E-4, in accordance with some embodiments.

The conductive lines 152 extend in the Y direction. That is, the conductive lines 152 have longitudinal axes parallel to the Y direction, in accordance with some embodiments. In some embodiments, the power branch lines 142B are electrically connected to the power supply lines 142A through the conductive lines 152 and the vias 150. As a result, the isolation gate stacks 125I are electrically connected to the power supply lines 142A through the power branch lines 142B (M1) and the conductive lines 152 (M2), in accordance with some embodiments. Specifically, the isolation gate stacks 125I₁, 125I₅, 125I₈ and 125I₁₂ and the contact plugs 136A₁, 136A₄, 136A₆ and 136A₇ are electrically connected to the power rail (Vss), and thus have the same voltage, in accordance with some embodiments. The isolation gate stacks 125I₂, 125I₆, 125I₉ and 125I₁₃ and the contact plugs 136A₂, 136A3, 136A₅ and 136A₈ are electrically connected to the power rail (Vdd), and thus have the same voltage, in accordance with some embodiments. In some embodiments, the functional gate stacks 125F are electrically isolated from the contact plugs 136. In some embodiments, the operation voltage applied to the functional gate stacks 125F is different than the voltages applied to Vdd power rail and Vss power rail. Although not illustrated, the second metal layer (M2) also includes some lines electrically connected to the signal lines 142C through the vias 150.

In some embodiments, the formation of the vias 150 and the second metal layer (M2) includes performing one or more patterning processes on the second intermetal dielectric layer 148 to form via openings (where the vias 150 are to be formed) and trenches (where the second metal layer (M2) are to be formed) using photolithography and etching processes. The etch processes may include dry etching such as RIE, NBE, ICP etch, CCP etch, another suitable method, or a combination thereof. The patterning processes for forming the vias 140 and via 142 may be formed separately. One or more conductive materials for the vias 150 and the second metal layer (M2) are then deposited using CVD, PVD, e-beam evaporation, ALD, ECP, ELD, another suitable method to overfill the via openings and the trenches. Afterward, a planarization process such as CMP and/or an etching back process is performed to remove an excess portion of the conductive materials from the upper surface of the second intermetal dielectric layer 148. After the planarization process, the upper surfaces of the second metal layer (M2) and the second intermetal dielectric layer 148 are substantially coplanar, in accordance with some embodiments.

The vias 150 and the second metal layer (M2) may have a multilayer structure. For example, a barrier layer (not shown) may optionally be deposited. The barrier layer may be made of tantalum (Ta), tantalum nitride (TaN), titanium (Ti), titanium nitride (TiN), cobalt tungsten (CoW), another suitable material, or a combination thereof. A glue layer (not shown) may optionally be deposited on the barrier layer (if formed). The glue layer may be made of tantalum nitride (TaN), titanium (Ti), titanium nitride (TiN), another suitable material, or a combination thereof. A metal bulk layer is then deposited on the glue layer (if formed) to fill the remainder of the via openings and the trenches. In some embodiments, the metal bulk layers are made of one or more conductive materials, such as copper (Cu), cobalt (Co), ruthenium (Ru), molybdenum (Mo), chromium (Cr), tungsten (W), manganese (Mn), rhodium (Rh), iridium (Ir), nickel (Ni), palladium (Pd), platinum (Pt), silver (Ag), golden (Au), aluminum (Al), another suitable metal material, or a combination thereof.

In some embodiments, the functional transistors FT1, FT2, FT3 and FT4 are electrically coupled to each other through the multilayer interconnect structure to form a NAND circuit in the first cell region C1. shown in FIGS. 2E, 2E-1, 2E-3 and 2E-4, in accordance with some embodiments. In some embodiments, the functional transistors FT5 and FT6 are electrically coupled to each other through the multilayer interconnect structure to form an inverter circuit in the second cell region C2. In some embodiments, the functional transistors FT7, FT8, FT9 and FT10 are electrically coupled to each other through the multilayer interconnect structure to form a NOR circuit in the third cell region C3. Additional components (such as third and fourth metal layers (M3 and M4)) may be formed over the semiconductor structure 100 to electrically couple the circuits in the cell regions C1, C2 and C3 to produce an integrated circuit. Although the embodiments are discussed in the context of nanostructure transistors, the aspect of the embodiments can be applied to other devices, e.g., FinFETs, planar transistors, or another applicable device.

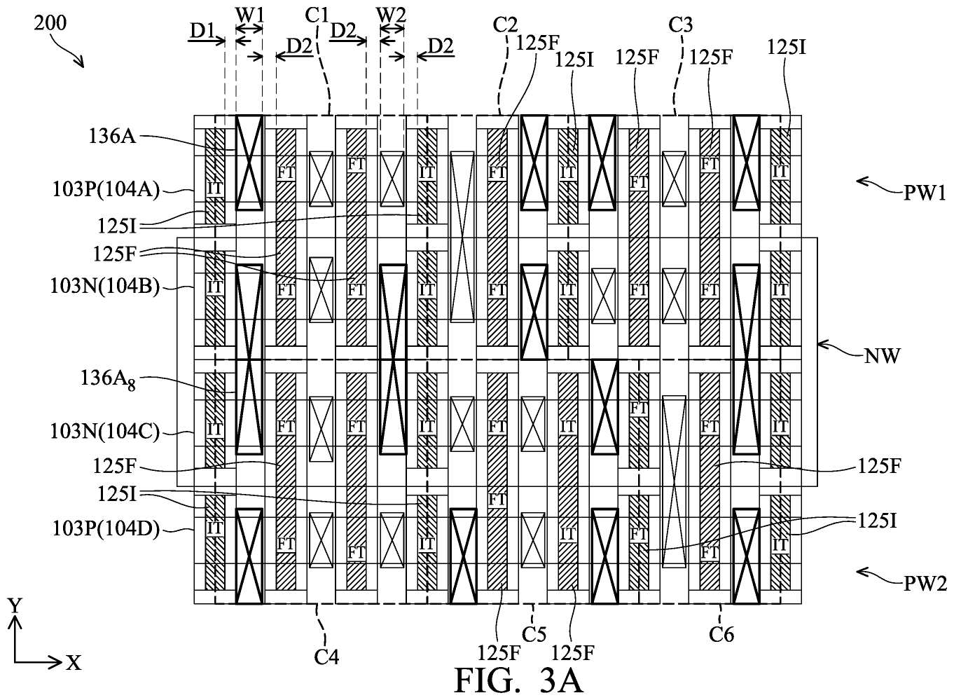

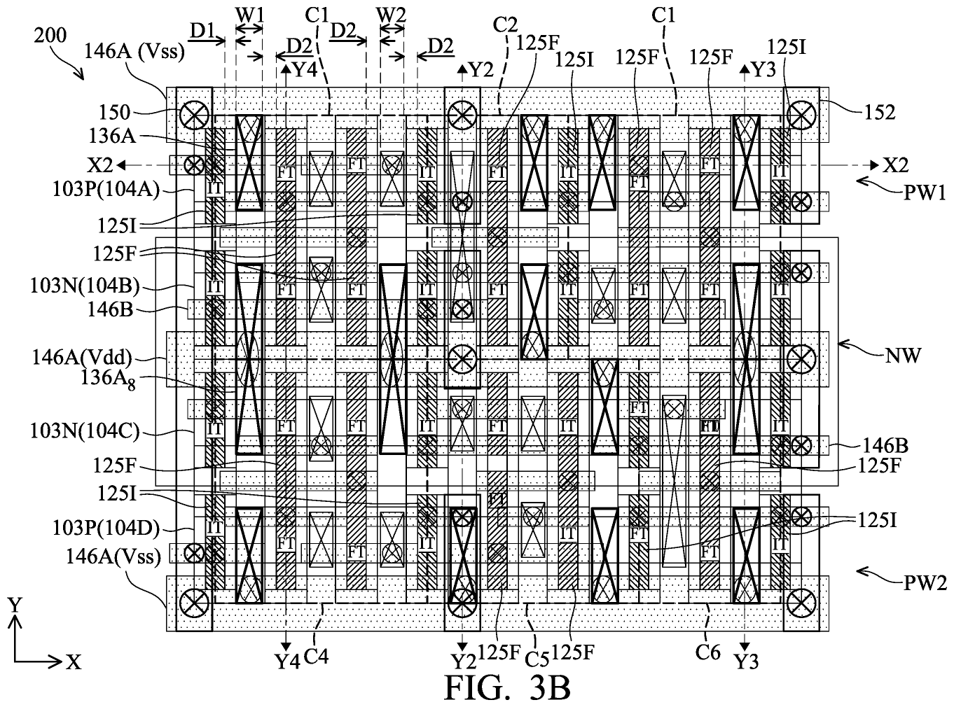

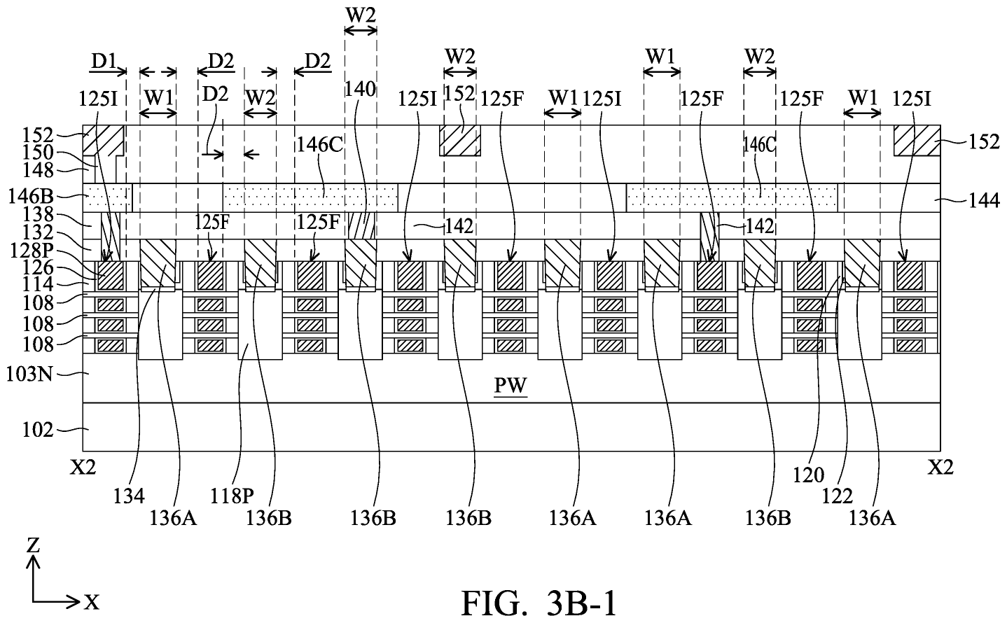

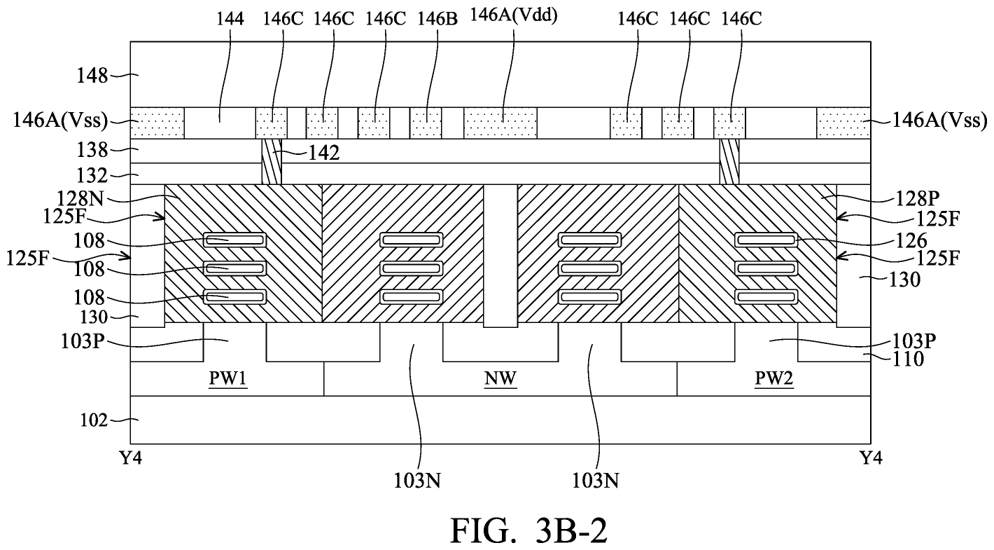

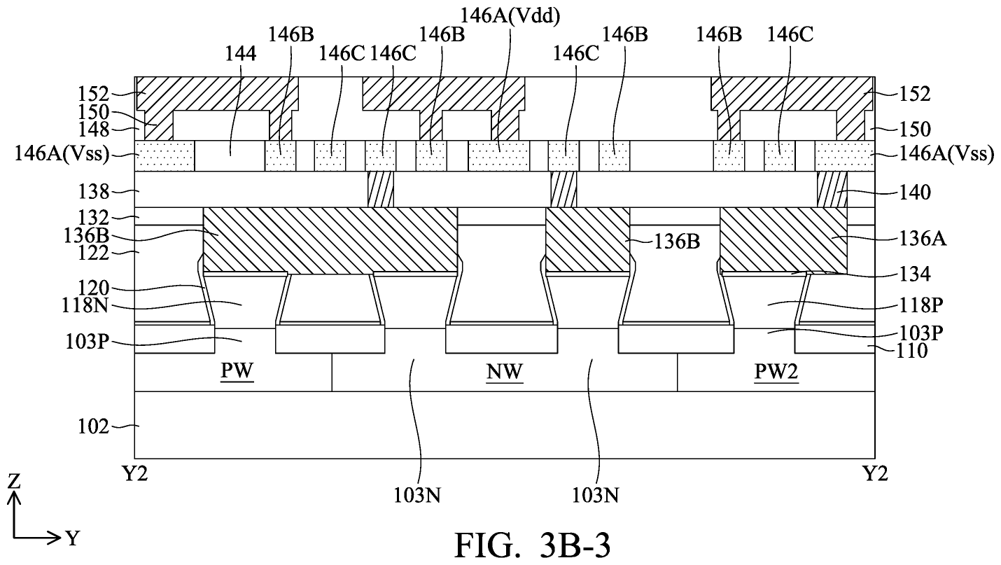

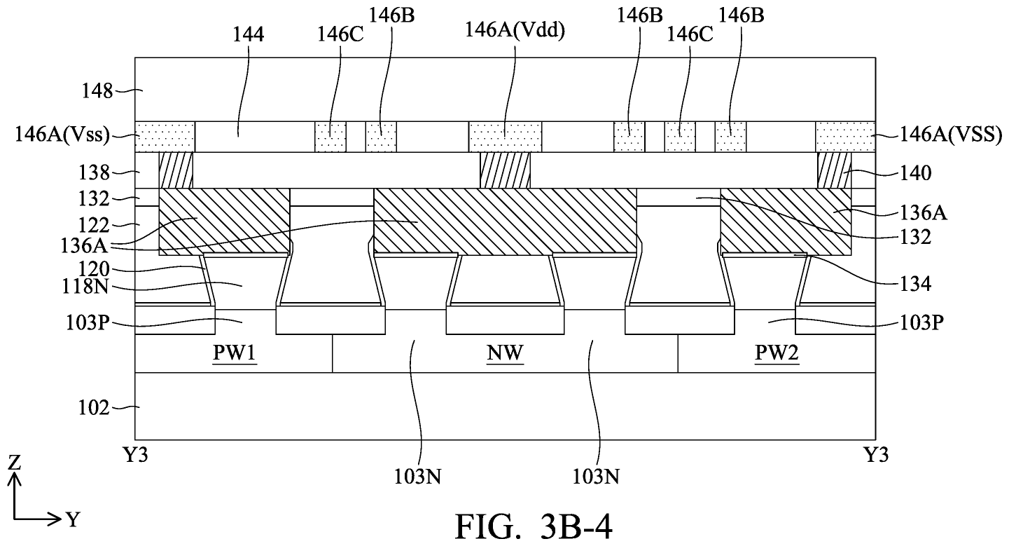

FIG. 3A to and 3B-4 are schematic views illustrating the formation of a semiconductor structure 200, in accordance with some embodiments of the disclosure. The embodiments of FIGS. 3A to and 3B-4 are similar to the embodiments of FIGS. 2A to 2E-4 except that the semiconductor structure 200 includes six cell regions.

FIG. 3A is a plan view (or a layout) of a semiconductor structure 200 after the formation of contact plugs 136A and contact plugs 136B, in accordance with some embodiments.

The semiconductor structure 200 includes a substrate 102, active regions 104 (including 104A-104D) over the substrate 102, and isolation gate stacks 125I and functional gate stacks 125F, in accordance with some embodiments. The substrate 102 includes an n-type well NW between p-type well PW1 and PW2, in accordance with some embodiments. The active region 104A is located on the p-type well PW1, the active regions 104B and 104C are located on the n-type well NW, and the active region 104C is located on the p-type well PW2, in accordance with some embodiments. In some embodiments, the isolation transistors IT are formed at the cross point between the active region 104 and the isolation gate stack 125I, and the functional transistors FT are formed at the cross point between the active region 104 and the functional gate stack 125F.

Some regions of the substrate 102 (or the semiconductor structure 200) are defined as cell regions C1-C6, in accordance with some embodiments. The cell regions C1, C2 and C3 are sequentially arranged in a first row (in the X direction), and the cell regions C4, C5 and C6 are sequentially arranged in a second row (in the X direction), in accordance with some embodiments. In some embodiments, the cell regions C1-C6 are standard cells and have the same cell height (in the Y direction). In some embodiments, the first cell region C1 and the fourth cell region C4 are NAND cells where NAND circuits are to be formed; the second cell region C2 and the sixth cell region C6 are inverter cells where inverter circuits are to be formed; and the third cell region C3 and the fifth cell region C5 are NOR cells where NOR circuits are to be formed. In some embodiments, the active regions 104A and 104B continuously extend through the cell regions C1, C2 and C3, and the active regions 104C and 104D continuously extend through the cell regions C4, C5 and C6. In some embodiments, the edges of the cell regions C1-C6 with respect to the X direction (extending in the Y direction) are aligned with the isolation gate stacks 125I.

The gate isolation structures 130 are located on the edges (or the boundaries) of the cells C1-C6, in accordance with some embodiments. At the edges of the cells C1-C6 with respect to the Y direction (extending in the X direction), the gate isolation structures 130 are disposed corresponding to each of the final gate stacks 125I and 125F, in accordance with some embodiments. At the edges of the cells C1-C6 with respect to the X direction, the gate isolation structures 130 are disposed corresponding to the isolation gate stacks 125I, in accordance with some embodiments.

In some embodiments, the contact plugs 136A land on the source terminals of the isolation transistors IT and the functional transistors FT. In some embodiments, the contact plugs 136B land on the drain terminals of the isolation transistors IT and the functional transistors FT. In some embodiments, the contact plugs 136A are disposed between the isolation transistors IT and the functional transistors FT (or between the isolation gate stacks 125I and the functional gate stacks 125F). In some embodiments, some of the contact plugs 136A extend from the cells C1 (and C3) into the cell regions C4 (and C6) and land on the two source/drain features (formed on the active regions 104B and 104C). In some embodiments, the contact plugs 136A are wider than the contact plugs 136B in the X direction (i.e., W1>W2). In some embodiments, the contact plugs 136A are offset toward the isolation gate stacks 125I. The contact plugs 136A with the greater width W1 may reduce the resistance (Rc and/or Rs), and the contact plugs 136B with the less width W2 may reduce the capacitance between the contact plugs 136B and the final gate stacks 125I or 125F, in accordance with some embodiments. Therefore, the performance and the reliability of the resulting semiconductor devices may be enhanced.

FIG. 3B is a plan view (or a layout) of a semiconductor structure 200 after the formation of a second metal layer (M2), in accordance with some embodiments. FIGS. 3B-1, 3B-2, 3B-3 and 3B-4 are cross-sectional views taken along line X2-X2, line Y4-Y4, Y2-Y2 and Y3-Y3 shown in FIG. 3B, respectively.

The steps as described above in FIG. 2D through 2E-4 are performed on the semiconductor structure 200, thereby forming the third interlayer dielectric layer 132, the vias 140 and 142, the first intermetal dielectric (IMD) layer 144, the first metal layer (M1), the second intermetal dielectric layer 148, the vias 150 and the second metal layer (M2), in accordance with some embodiments.

The power supply lines 146A in the first metal layer (M1) extend along and overlap the edges of the cells C1, C2 and C3 with respect to the Y direction, in accordance with some embodiments. The Vss power rails are electrically connected to the source terminals of the n-channel transistors in the p-type wells PW1 and PW2 through the vias 140 and the contact plugs 136A, in accordance with some embodiments. The Vdd power rail is electrically connected to the source terminals of the p-channel transistors in the n-type well NW through the vias 140 and the contact plugs 136A, in accordance with some embodiments. The isolation gate stacks 125I are electrically connected to the power supply lines 142A through the power branch lines 142B in the first metal layer (M1) and the conductive lines 152 in the second metal layer (M2), in accordance with some embodiments.

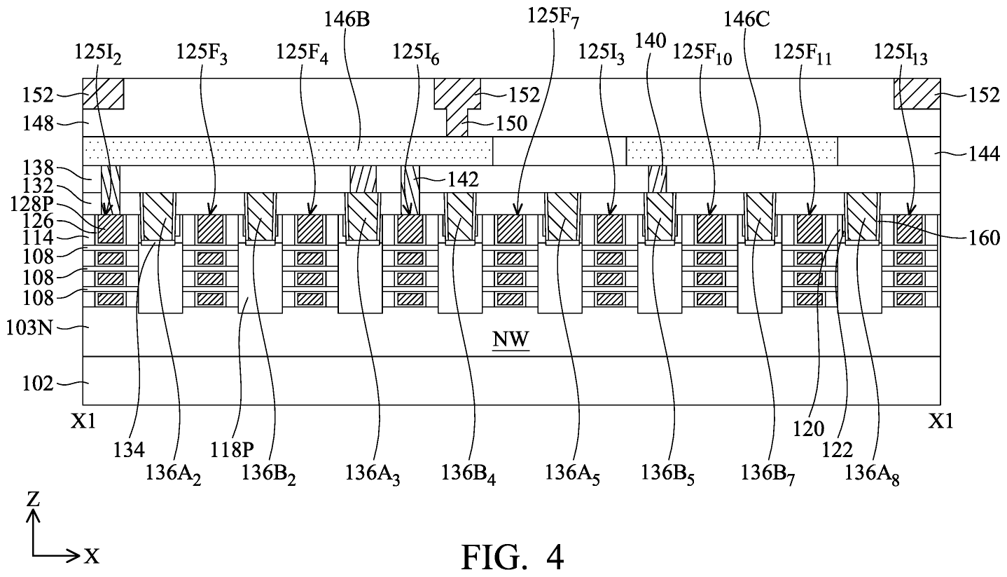

FIG. 4 is a modification of the semiconductor structure 100 of FIG. 2E-1, in accordance with some embodiments of the disclosure. The embodiments of FIG. 4 are similar to the embodiments of FIG. 2E-1 except for a contact liner surrounding the contact plug.

A contact liner 160 is formed along the sidewalls of the contact openings before the conductive material for contact plugs 136A and 136B is deposited, in accordance with some embodiments. In some embodiments, the contact liner 160 is configured to prevent the metal from the contact plugs from diffusing into the dielectric material. In some embodiments, the contact liner 160 is made of silicon nitride (SiN), silicon oxynitride (SiON), silicon oxynitride (SiOC), silicon oxycarbonitride (SiOCN), or a combination thereof, and/or another suitable dielectric material. In some embodiments, the contact liner 160 is made of a different material than the first interlayer dielectric layer 122 and the second interlayer dielectric layer 132. In some embodiments, the material the contact liner 160 is deposited using such as ALD, CVD (such as LPCVD, PECVD, or HDP-CVD), another suitable method, or a combination thereof, and followed by an etching back process. A vertical portion of the dielectric material left on the sidewalls of the contact opening serves as the contact liner 160, in accordance with some embodiments. In some embodiments, the contact liner 160 has a thickness (along the sidewalls of the contact openings) in a range from about 0.3 nm to about 2 nm. Afterward, the conductive material for contact plugs 136A and 136B is deposited to fill the remainder of the contact openings, in accordance with some embodiments.

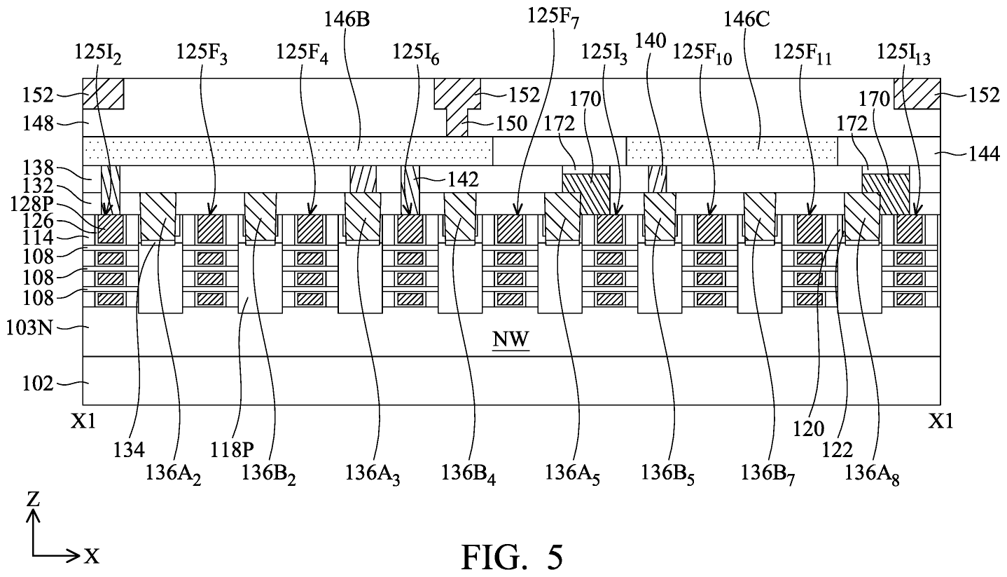

FIG. 5 is a modification of the semiconductor structure 100 of FIG. 2E-1, in accordance with some embodiments of the disclosure. The embodiments of FIG. 5 are similar to the embodiments of FIG. 2E-1 except that some of the isolation gate stacks and some of the contact plugs are connected by the butt contact plugs.

Contacts plugs 170 are formed in and/or through the third interlayer dielectric layer 138 and the second interlayer dielectric layer 132 and land on the isolation gate stacks 125I and the contact plugs 136A, in accordance with some embodiments. In some embodiments, the contact plugs 170 may be also referred to as butt contact plugs. The contact plugs 136A are electrically connected to the isolation gate stacks 125I, and thus the contact plugs 136A and the isolation gate stacks 125I have the same voltage (i.e., zero voltage difference). The isolation gate stacks 125I are electrically connected to the power supply lines 142A through contact plugs 170, the contact plugs 136A and the via 140, in accordance with some embodiments. As a result, the number of the power branch lines 146B may be reduced, which may relax the overlay/CD window of the photolithography for forming the first metal layer (M1).

In some embodiments, the formation of the contact plugs 170 includes patterning the third interlayer dielectric layer 138 and the second interlayer dielectric layer 132 to form openings (where the contact plugs 170 are to be formed) using photolithography and etching processes until the isolation gate stacks 125I and the contact plugs 136A are exposed. The etch processes may include dry etching such as RIE, NBE, ICP etch, CCP etch, another suitable method, or a combination thereof. In some embodiments, one or more conductive materials are deposited using CVD, PVD, e-beam evaporation, ALD, electroplating (ECP), electroless deposition (ELD), another suitable method, or a combination thereof to overfill the openings. The one or more conductive materials over the upper surface of the second interlayer dielectric layer 132 are then planarized using, for example, CMP. In some embodiments, the contact plugs 170 are made of conductive material such as cobalt (Co), nickel (Ni), tungsten (W), titanium (Ti), TiN, TaN, tantalum (Ta), copper (Cu), rhodium (Rh), iridium (Ir), platinum (Pt), aluminum (Al), ruthenium (Ru), molybdenum (Mo), another suitable material, or a combination thereof.

Afterward, the contact plugs 170 are recessed by an etching process, and a dielectric layer 172 is then formed over the recessed contact plugs 170, in accordance with some embodiments. In some embodiments, the dielectric layer 172 is made of silicon oxide (SiO), silicon nitride (SiN), silicon oxynitride (SiON), USG, BPSG, FSG, PSG, BSG, and/or another suitable dielectric material. The contact plugs 170 is separated from the first metal layer (M1) by the dielectric layer 172.

As described above, the semiconductor structure includes a first contact plug 136A between an isolation transistor IT and a functional transistor FT and a second contact plug 136B between two functional transistors FT. As measured in a direction parallel to the longitudinal axis of the active region 104, the first contact plug 136A is wider than the second contact plug 136B. The first contact plug 136A is closer to the isolation gate stack 125I than to the functional gate stack 125F. As a result, the first contact plug 136A with a greater width may reduce the resistance, and the second contact plug with a less width may reduce the risk of the leak (or breakdown) between the contact plugs 136B and the final gate stacks 125I or 125F and/or the capacitance between the contact plug 136B and the functional gate stack 125I or 125F, in accordance with some embodiments. Therefore, the performance and the reliability of the resulting semiconductor devices may be enhanced.

Embodiments of a semiconductor structure and the method for forming the same may be provided. The semiconductor structure may include a functional transistor and an isolation transistor, and a contact plug on the source/drain feature shared by the functional transistor and the isolation transistor. Because the contact plug and the gate stack of the isolation transistor are electrically connected to each other, the contact plug may be close to the isolation transistor without negatively impacting the contact-to-gate isolation margin. As a result, the width of the contact plug may be enlarged toward the gate stack of the isolation transistor, and thus the performance of the resulting semiconductor devices may be enhanced.

In some embodiments, a semiconductor structure is provided. The semiconductor structure includes a first transistor. The first transistor includes a first set of nanostructures vertically stacked and spaced apart from one another, a first gate stack wrapping around the first set of nanostructures and extending in a first direction, and a first source/drain feature and a second source/drain feature adjoining opposite sides of the first set of nanostructures. The semiconductor structure also includes a first contact plug over the first source/drain feature, and a second contact plug over the second source/drain feature. As measured in a second direction which is perpendicular to the first direction, a width of the second contact plug is greater than a width of the first contact plug.

In some embodiments, a semiconductor structure is provided. The semiconductor structure includes a first functional transistor including a first gate stack over an active region, and an isolation transistor including a second gate stack over the active region. The first functional transistor and the isolation transistor share a first source/drain feature. The semiconductor structure also includes a first contact plug directly above the first source/drain feature between the first gate stack and the second gate stack. A distance between the first contact plug and the first gate stack is greater than a distance between the first contact plug and the second gate stack of the isolation transistor.

In some embodiments, a semiconductor structure is provided. The semiconductor structure includes a first circuit in a first cell region and an isolation transistor. The first circuit includes a first gate stack and a second gate stack, the isolation transistor includes a third gate stack, and the first gate stack, the second gate stack and the third gate stack are sequentially arranged in a first direction. The semiconductor structure also includes a first contact plug between the first gate stack and the second gate stack, a second contact plug between the second gate stack and the third gate stack, and a power supply line over the first contact plug and the second contact plug. In the first direction, the second contact plug is wider than the first contact plug. Both the second contact plug and the third gate stack are electrically connected to the power supply line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first transistor comprising a first set of nanostructures vertically stacked and spaced apart from one another, a first gate stack wrapping around the first set of nanostructures and extending in a first direction, and a first source/drain feature and a second source/drain feature adjoining opposite sides of the first set of nanostructures;
a first contact plug over the first source/drain feature; and
a second contact plug over the second source/drain feature, wherein as measured in a second direction which is perpendicular to the first direction, a width of the second contact plug is greater than a width of the first contact plug.

2. The semiconductor structure as claimed in claim 1, wherein a distance between the first contact plug and the first gate stack is greater than a distance between the second contact plug and the first gate stack.

3. The semiconductor structure as claimed in claim 1, further comprising:
a metal layer over the first contact plug and the second contact plug, wherein the second contact plug is electrically connected to the first gate stack through the metal layer.

4. The semiconductor structure as claimed in claim 1, wherein the first contact plug is electrically isolated from the first gate stack.

5. The semiconductor structure as claimed in claim 1, further comprising:
a second transistor comprising a second set of nanostructures vertically stacked and spaced apart from one other, and a second gate stack wrapping around the second set of nanostructures and extending in the first direction; and
a gate isolation structure sandwiched between and in contact with the first gate stack and the second gate stack.

6. The semiconductor structure as claimed in claim 5, wherein the first transistor is a p-channel transistor and the second transistor is an n-channel transistor.

7. The semiconductor structure as claimed in claim 1, further comprising:
a second transistor comprising a second set of nanostructures vertically stacked and spaced apart from one another, and a second gate stack wrapping around the second set of nanostructures and extending in the first direction, the second source/drain feature adjoining a side of the second set of nanostructures, and a third source/drain feature adjoining another side of the second set of nanostructures,
wherein a distance between the second contact plug and the first gate stack is less than a distance between the second contact plug and the second gate stack.

8. The semiconductor structure as claimed in claim 1, wherein a ratio of the width of the second contact plug to the width of the first contact plug is in a range from about 1.05 to about 1.25.

9. A semiconductor structure, comprising:
a first functional transistor comprising a first gate stack over an active region;
an isolation transistor comprising a second gate stack over the active region, wherein the first functional transistor and the isolation transistor share a first source/drain feature; and
a first contact plug directly above the first source/drain feature between the first gate stack and the second gate stack, wherein a distance between the first contact plug and the first gate stack is greater than a distance between the first contact plug and the second gate stack.

10. The semiconductor structure as claimed in claim 9, further comprising:
a second functional transistor comprising a third gate stack over the active region, wherein the first functional transistor and the second functional transistor share a second source/drain feature; and
a second contact plug directly above the second source/drain feature between the first gate stack and the third gate stack, wherein the first contact plug is longer and wider than the second contact plug.

11. The semiconductor structure as claimed in claim 9, further comprising:
a second functional transistor comprising a third gate stack over the active region, wherein the isolation transistor and the second functional transistor share a second source/drain feature, wherein the active region comprises a fin element continuously extending below the first gate stack, the second gate stack and the third gate stack.

12. The semiconductor structure as claimed in claim 11, further comprising:
a NAND circuit comprising the first functional transistor; and
an inverter circuit comprising the second functional transistor, wherein the isolation transistor is located between the NAND circuit and the inverter circuit.

13. The semiconductor structure as claimed in claim 9, further comprising:
a metal layer over the first contact plug, wherein the metal layer comprises a power supply line, and both the first contact plug and the second gate stack are electrically connected to the power supply line.

14. The semiconductor structure as claimed in claim 9, further comprising:
an interlayer dielectric layer surrounding the first contact plug; and
a second contact plug in the interlayer dielectric layer, wherein the second contact plug is in contact with both the first contact plug and the second gate stack.

15. The semiconductor structure as claimed in claim 9, wherein the active region includes a first set of nanostructures wrapped by the first gate stack and a second set of nanostructures wrapped by the second gate stack.

16. The semiconductor structure as claimed in claim 9, further comprising:
a contact etching stop layer over the first source/drain feature, wherein the contact etching stop layer includes a first vertical portion along a first sidewall of the first gate stack and a second vertical portion along a second sidewall of the second gate stack; and
an interlayer dielectric layer over the contact etching stop layer, wherein the first contact plug is in contact with the second vertical portion of the contact etching stop layer and separated from the first vertical portion of the contact etching stop layer by the interlayer dielectric layer.

17. A semiconductor structure, comprising:
a first circuit in a first cell region, the first circuit comprising a first gate stack and a second gate stack;
an isolation transistor comprising a third gate stack, wherein the first gate stack, the second gate stack and the third gate stack are sequentially arranged in a first direction;
a first contact plug between the first gate stack and the second gate stack;
a second contact plug between the second gate stack and the third gate stack, wherein in the first direction, the second contact plug is wider than the first contact plug; and
a power supply line over the first contact plug and the second contact plug, wherein both the second contact plug and the third gate stack are electrically connected to the power supply line.

18. The semiconductor structure as claimed in claim 17, further comprising:
a second circuit in a second cell region, the second circuit comprising a fourth gate stack, wherein the third gate stack is located between the second gate stack and the fourth gate stack; and
a third contact plug between the third gate stack and the fourth gate stack, wherein in the first direction, the second contact plug is wider than the third contact plug.

19. The semiconductor structure as claimed in claim 17, further comprising:
a second circuit in a second cell region, the second circuit comprising a fourth gate stack and a fifth gate stack;
a second isolation transistor comprising a sixth gate stack, wherein the fourth gate stack, the fifth gate stack and the sixth gate stack are sequentially arranged in the first direction, wherein the sixth gate stack is electrically connected to the power supply line;
a first gate isolation structure sandwiched between the first gate stack and the fourth gate stack;
a second gate isolation structure sandwiched between the second gate stack and the fifth gate stack; and
a third gate isolation structure sandwiched between the third gate stack and the sixth gate stack.

20. The semiconductor structure as claimed in claim 19, wherein the second contact plug extends between the fifth gate stack and the sixth gate stack.
